(19) United States
(12) Patent Application Publication
(10) Pub. No.: US 2025/0089364 A1
(43) Pub. Date: Mar. 13, 2025

(54) INTEGRATED CIRCUIT, SYSTEM AND METHOD OF FORMING THE SAME

(71) Applicant: TAIWAN SEMICONDUCTOR MANUFACTURING COMPANY, LTD., Hsinchu (TW)

(72) Inventors: Cheng-Ling WU, Hsinchu (TW); Chih-Liang CHEN, Hsinchu (TW); Chi-Yu LU, Hsinchu (TW); Yi-Yi CHEN, Hsinchu (TW); Ting-Yun WU, Hsinchu (TW)

(21) Appl. No.: 18/464,508

(22) Filed: Sep. 11, 2023

(51) Int. Cl. H01L 27/12; H03K 17/687

(52) U.S. Cl. CPC H10D 86/60; H03K 17/6871; H10D 86/021; H10D 86/441; H03K 19/20

(57) ABSTRACT

A integrated circuit includes a first, a second, a third, and a fourth gate, a first input pin and a first conductor. The first and third gate are on a first level. The second and fourth gate are on a second level. The second gate is coupled to the first gate. The fourth gate is coupled to the third gate. The first input pin extends in a second direction, is on a first metal layer above a front-side of a substrate, is coupled to the first gate, and configured to receive a first input signal. The first input pin is electrically coupled to the third gate by the first, second or fourth gate. The first conductor extends in the first direction, is on a second metal layer below a back-side of the substrate, and is coupled to the second and fourth gate.

### BACKGROUND

The semiconductor integrated circuit (IC) industry has produced a wide variety of digital devices to address issues in a number of different areas. Some of these digital devices, such as memory macros, are configured for the storage of data. As ICs have become smaller and more complex, the resistance of conductive lines within these digital devices is also changed affecting the operating voltages of these digital devices and overall IC performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a circuit diagram of an integrated circuit, in accordance with some embodiments.

FIGS. 2A-2B are corresponding diagrams of corresponding portions of a layout design of a corresponding integrated circuit, in accordance with some embodiments.

FIGS. 3A-3E are diagrams of an integrated circuit, in accordance with some embodiments.

FIG. 4A is a block diagram of an integrated circuit, in accordance with some embodiments.

FIG. 4B is a circuit diagram of an integrated circuit, in accordance with some embodiments.

FIGS. 5A-5B are diagrams of an integrated circuit, in accordance with some embodiments.

FIGS. 6A-6D are diagrams of an integrated circuit, in accordance with some embodiments.

FIG. 7A-7B are functional flow charts of corresponding methods of manufacturing an IC device, in accordance with some embodiments.

FIG. 8 is a flow chart of a method of manufacturing an integrated circuit, in accordance with some embodiments.

FIG. 9 is a flowchart of a method of generating a layout design of an integrated circuit, in accordance with some embodiments.

FIG. 10 is a schematic view of a system for designing an IC layout design and manufacturing an IC circuit, in accordance with some embodiments.

FIG. 11 is a block diagram of an IC manufacturing system, and an IC manufacturing flow associated therewith, in accordance with at least one embodiment of the present disclosure.

### DETAILED DESCRIPTION

The following disclosure provides different embodiments, or examples, for implementing features of the provided subject matter. Specific examples of components, materials, values, steps, arrangements, or the like, are described below to simplify the present disclosure. These are, of course, merely examples and are not limiting. Other components, materials, values, steps, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, an integrated circuit includes a first gate and a second gate. In some embodiments, the first gate is on a first level. In some embodiments, the second gate is on a second level. In some embodiments, the second level is below the first level. In some embodiments, the second gate is coupled to the first gate.

In some embodiments, the integrated circuit further includes a third gate on the first level. In some embodiments, the third gate is separated from the first gate in a first direction.

In some embodiments, the integrated circuit further includes a fourth gate on the second level.

In some embodiments, the fourth gate is separated from the second gate in the first direction. In some embodiments, the fourth gate is coupled to the third gate.

In some embodiments, the integrated circuit further includes a first input pin extending in a second direction. In some embodiments, the second direction is different from the first direction. In some embodiments, the first input pin is on a first metal layer. In some embodiments, the first metal layer is above a front-side of a substrate. In some embodiments, the first input pin is coupled to at least the first gate. In some embodiments, the first input pin is configured to receive a first input signal.

In some embodiments, the integrated circuit further includes a first conductor extending in the first direction. In some embodiments, the first conductor is coupled to at least the second gate and the fourth gate. In some embodiments, the first conductor is on a second metal layer. In some embodiments, the second metal layer is below a back-side of the substrate opposite from the front-side of the substrate.

In some embodiments, the first input pin is electrically coupled to the third gate by at least the first gate, the second gate or the fourth gate. In some embodiments, the first input pin is electrically coupled to the third gate from the back-side of the substrate by at least the second gate or the fourth gate.

In some embodiments, by electrically coupling the first input pin to the third gate from the back-side of the substrate, one or more back-side metallization levels can be utilized as additional routing resources thereby resulting in an integrated circuit having at least one of a reduced pitch, a smaller area or a smaller standard cell than other approaches.

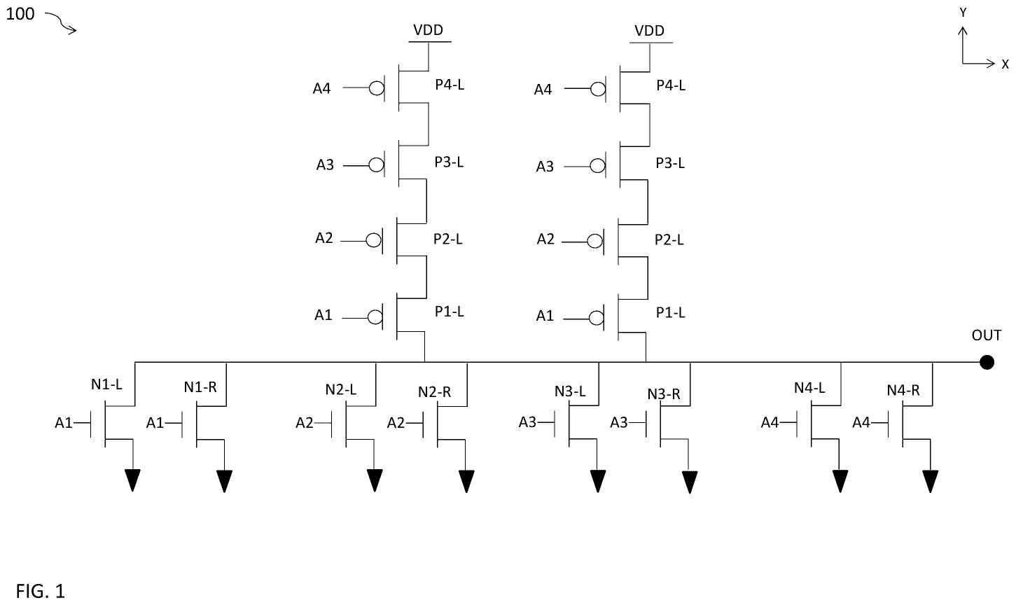

FIG. 1 is a circuit diagram of an integrated circuit 100, in accordance with some embodiments.

In some embodiments, integrated circuit 100 is a 4-2 NOR LOGIC GATE circuit. A 4-2 NOR LOGIC GATE circuit is used for illustration, other types of circuits are within the scope of the present disclosure. In some embodiments, other numbers of inputs or transistors for integrated circuit 100 are within the scope of the present disclosure.

Integrated circuit 100 includes P field effect transistors (PFET) P1-L, P2-L, P3-L, P4-L, P1-R, P2-R, P3-R and P4-R and N field effect transistors (NFET) N1-L, N2-L, N3-L, N4-L, N1-R, N2-R, N3-R and N4-R.

A gate terminal of PFET transistor P1-L is configured as an input node (not labelled) configured to receive an input signal A1. A gate terminal of NFET transistor N1-L is configured as an input node (not labelled) configured to receive input signal A1.

A gate terminal of PFET transistor P1-R is configured as an input node (not labelled) configured to receive input signal A1. A gate terminal of NFET transistor N1-R is configured as an input node (not labelled) configured to receive input signal A1.

In some embodiments, at least one of the gate terminal of PFET transistor P1-L, the gate terminal of NFET transistor N1-L, the gate terminal of PFET transistor P1-R or the gate terminal of NFET transistor N1-R is coupled to another of at least one of the gate terminal of PFET transistor P1-L, the gate terminal of NFET transistor N1-L, the gate terminal of PFET transistor P1-R or the gate terminal of NFET transistor N1-R.

A gate terminal of PFET transistor P2-L is configured as an input node (not labelled) configured to receive an input signal A2. A gate terminal of NFET transistor N2-L is configured as an input node (not labelled) configured to receive input signal A2.

A gate terminal of PFET transistor P2-R is configured as an input node (not labelled) configured to receive input signal A2. A gate terminal of NFET transistor N2-R is configured as an input node (not labelled) configured to receive input signal A2.

In some embodiments, at least one of the gate terminal of PFET transistor P2-L, the gate terminal of NFET transistor N2-L, the gate terminal of PFET transistor P2-R or the gate terminal of NFET transistor N2-R is coupled to another of at least one of the gate terminal of PFET transistor P2-L, the gate terminal of NFET transistor N2-L, the gate terminal of PFET transistor P2-R or the gate terminal of NFET transistor N2-R.

A gate terminal of PFET transistor P3-L is configured as an input node (not labelled) configured to receive an input signal A3. A gate terminal of NFET transistor N3-L is configured as an input node (not labelled) configured to receive input signal A3.

A gate terminal of PFET transistor P3-R is configured as an input node (not labelled) configured to receive input signal A3. A gate terminal of NFET transistor N3-R is configured as an input node (not labelled) configured to receive input signal A3.

In some embodiments, at least one of the gate terminal of PFET transistor P3-L, the gate terminal of NFET transistor N3-L, the gate terminal of PFET transistor P3-R or the gate terminal of NFET transistor N3-R is coupled to another of at least one of the gate terminal of PFET transistor P3-L, the gate terminal of NFET transistor N3-L, the gate terminal of PFET transistor P3-R or the gate terminal of NFET transistor N3-R.

A gate terminal of PFET transistor P4-L is configured as an input node (not labelled) configured to receive an input signal A4. A gate terminal of NFET transistor N4-L is configured as an input node (not labelled) configured to receive input signal A4.

A gate terminal of PFET transistor P4-R is configured as an input node (not labelled) configured to receive input signal A4. A gate terminal of NFET transistor N4-R is configured as an input node (not labelled) configured to receive input signal A4.

In some embodiments, at least one of the gate terminal of PFET transistor P4-L, the gate terminal of NFET transistor N4-L, the gate terminal of PFET transistor P4-R or the gate terminal of NFET transistor N4-R is coupled to another of at least one of the gate terminal of PFET transistor P4-L, the gate terminal of NFET transistor N4-L, the gate terminal of PFET transistor P4-R or the gate terminal of NFET transistor N4-R.

A source terminal of PFET transistor P4-L and a source terminal of PFET transistor P4-R are coupled to the voltage supply VDD. In some embodiments, the source terminal of PFET transistor P4-L and the source terminal of PFET transistor P4-R are coupled together.

A drain terminal of PFET transistor P4-L and a source terminal of PFET transistor P3-L are coupled to each other. A drain terminal of PFET transistor P4-R and a source terminal of PFET transistor P3-R are coupled to each other.

A drain terminal of PFET transistor P3-L and a source terminal of PFET transistor P2-L are coupled to each other. A drain terminal of PFET transistor P3-R and a source terminal of PFET transistor P2-R are coupled to each other.

A drain terminal of PFET transistor P2-L and a source terminal of PFET transistor P1-L are coupled to each other. A drain terminal of PFET transistor P2-R and a source terminal of PFET transistor P1-R are coupled to each other.

Each of a source terminal of NFET transistor N1-L, a source terminal of NFET transistor N2-L, a source terminal of NFET transistor N3-L, a source terminal of NFET transistor N4-L, a source terminal of NFET transistor N1-R, a source terminal of NFET transistor N2-R, a source terminal of NFET transistor N3-R and a source terminal of NFET transistor N4-R is coupled to a reference voltage supply VSS.

In some embodiments, at least one of the source terminal of NFET transistor N1-L, the source terminal of NFET transistor N2-L, the source terminal of NFET transistor N3-L, the source terminal of NFET transistor N4-L, the source terminal of NFET transistor N1-R, the source terminal of NFET transistor N2-R, the source terminal of NFET transistor N3-R or the source terminal of NFET transistor N4-R is coupled to another of at least one of the source terminal of NFET transistor N1-L, the source terminal of NFET transistor N2-L, the source terminal of NFET transistor N3-L, the source terminal of NFET transistor N4-L, the source terminal of NFET transistor N1-R, the source terminal of NFET transistor N2-R, the source terminal of NFET transistor N3-R or the source terminal of NFET transistor N4-R.

Each of a drain terminal of NFET transistor N1-L, a drain terminal of NFET transistor N2-L, a drain terminal of NFET transistor N3-L, a drain terminal of NFET transistor N4-L, a drain terminal of NFET transistor N1-R, a drain terminal of NFET transistor N2-R, a drain terminal of NFET transistor N3-R, a drain terminal of NFET transistor N4-R, a drain terminal of PFET transistor P1-L, and a drain terminal of PFET transistor P1-R are coupled to each other, and are configured as an output node OUT.

Other circuits, other types of transistors, and/or quantities of transistors are within the scope of various embodiments. For example, in some embodiments, integrated circuit 100 includes other types of NOR LOGIC GATE circuits, such as a 4-1 NOR LOGIC GATE. Other values of at least input signal A1, A2, A3 or A4 are within the scope of various embodiments.

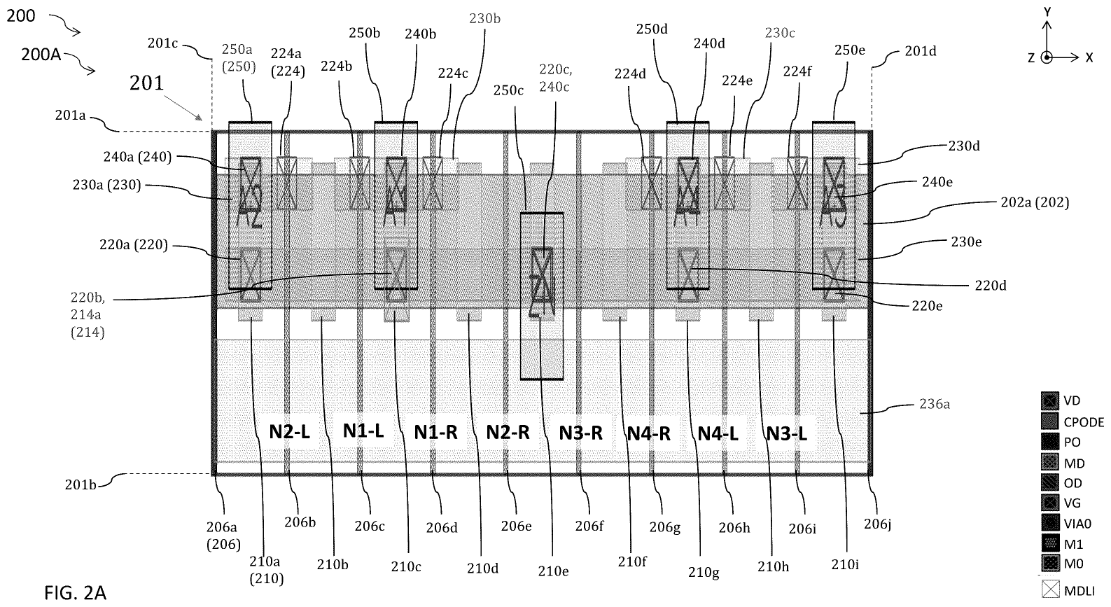

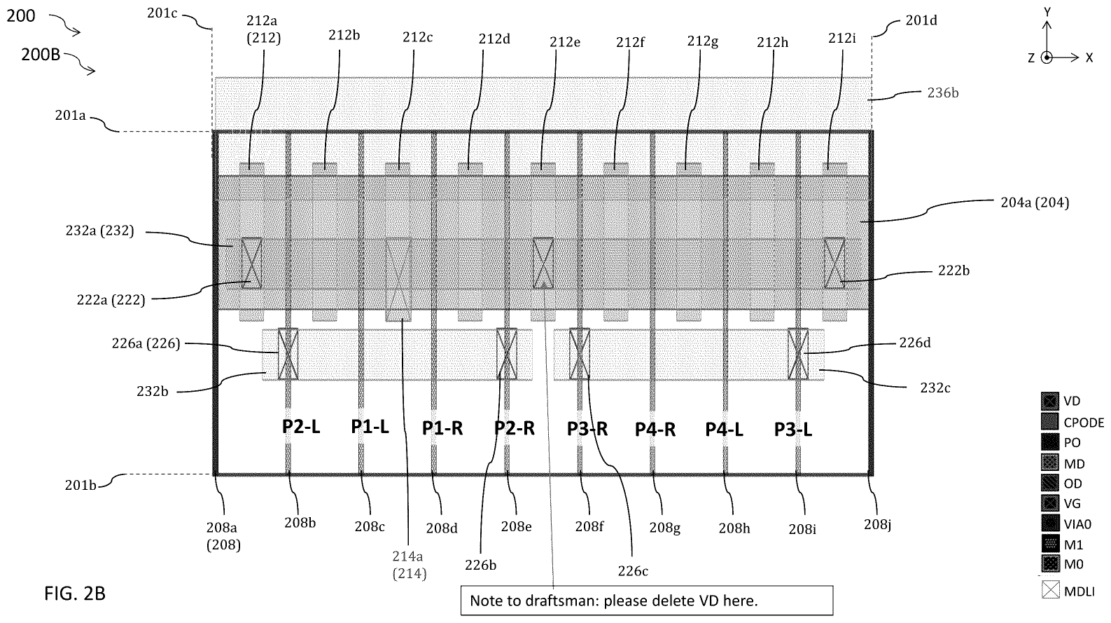

FIGS. 2A-2B are corresponding diagrams of corresponding portions 200A-200B of a layout design 200 of a corresponding integrated circuit 300, in accordance with some embodiments.

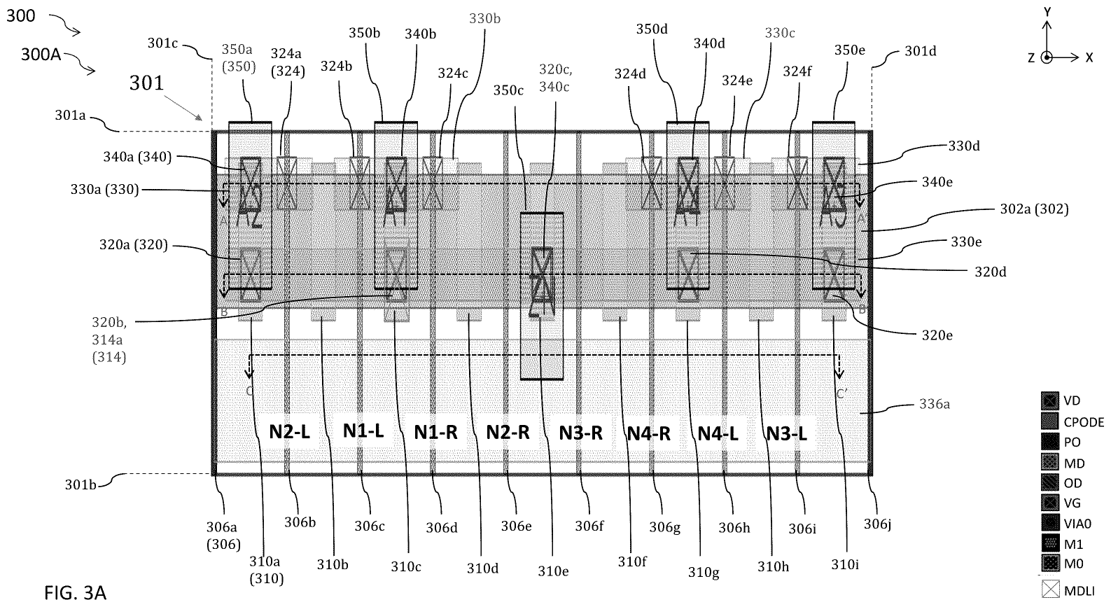

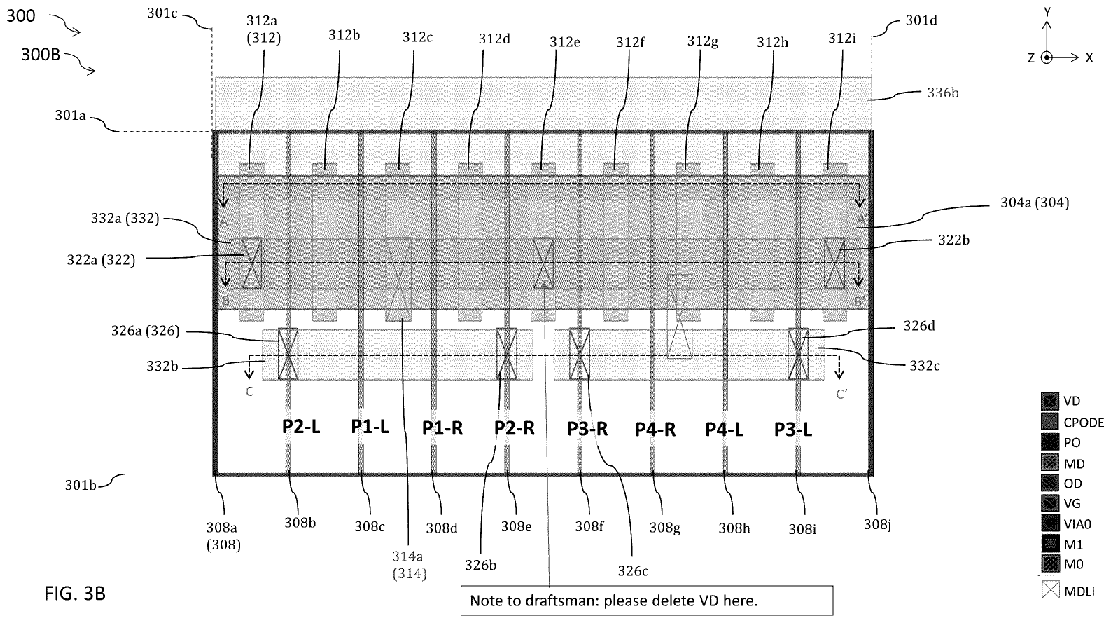

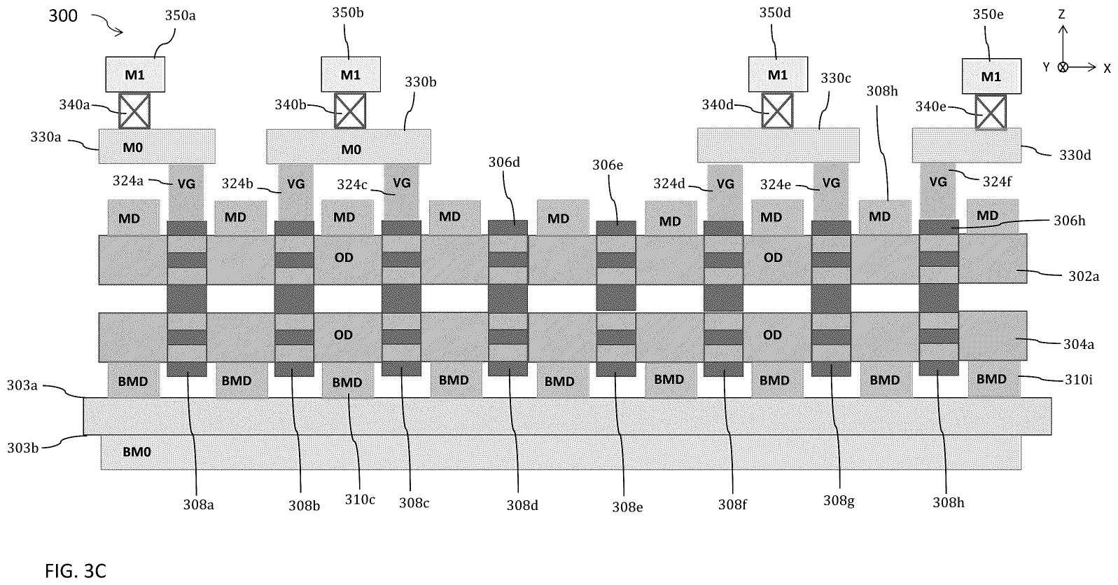

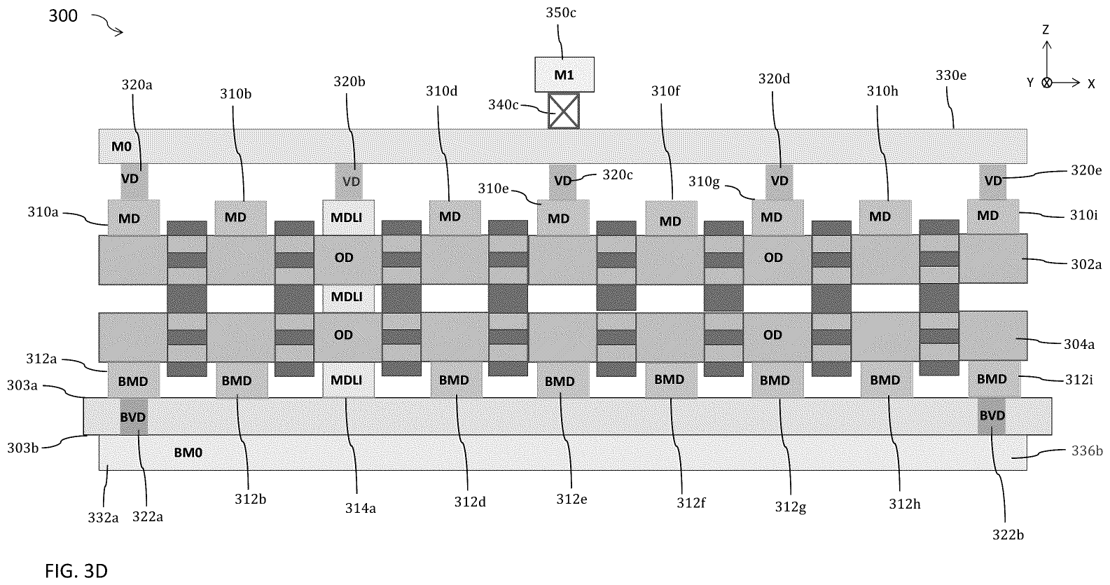

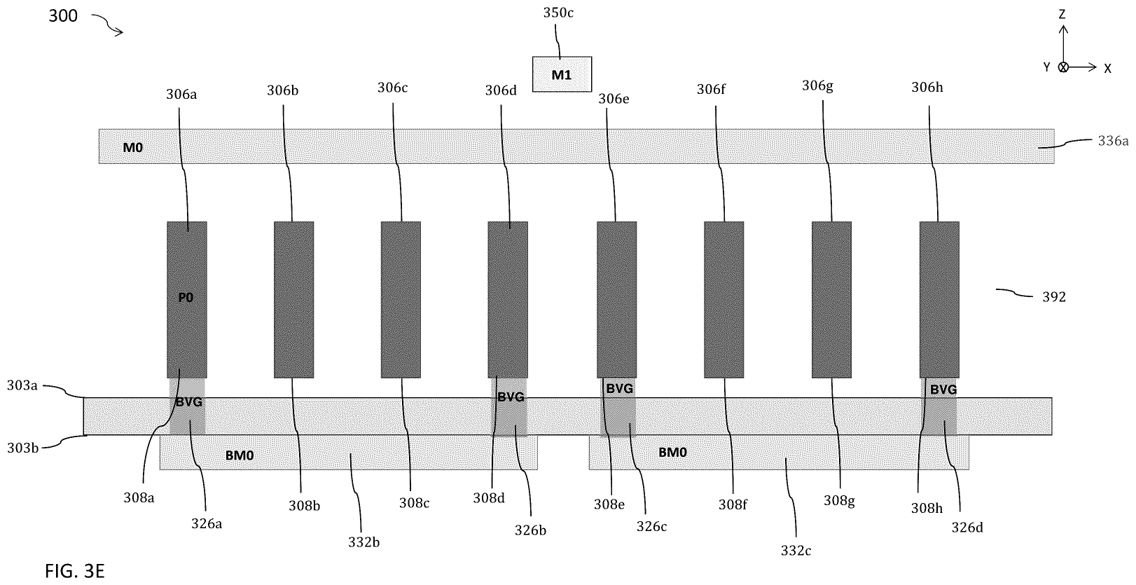

Layout design 200 is a layout of integrated circuit 100 of FIG. 1. Layout design 200 is a layout of an integrated circuit 300 of FIGS. 3A-3E.

Portion 200A includes one or more features of layout design 200 of an active level or an oxide diffusion (OD) level, a gate (POLY) level, a metal over diffusion (MD) level, a metal over diffusion local interconnect (MDLI) level, a metal 0 (M0) level, a metal 1 (M1) level, a via over gate (VG) level, a via over diffusion (VD) level, and a via over metal 0 (V0) level.

Portion 200B includes one or more features of layout design 200 of the OD level, the POLY level, a backside metal over diffusion (BMD) level, the MDLI level, a backside metal 0 (BM0) level, a backside via over gate (BVG) level, and a backside via over diffusion (BVD) level. In some embodiments, portion 200B further includes one or more features of layout design 200 of a backside metal 1 (BM1) or a backside via over metal 0 (BV0) level.

FIGS. 2A-2B are corresponding diagrams of corresponding portions 200A-200B of layout design 200, simplified for ease of illustration.

For ease of illustration, some of the labeled elements of one or more of FIGS. 1-6D are not labelled in one or more of FIGS. 1-6D. In some embodiments, layout design 200 includes additional elements not shown in FIGS. 2A-2B.

Layout design 200 includes one or more features of the OD level, the POLY level, the MD level, the MDLI level, the M0 level, the VG level, the VD level, the M1 level, the V0 level, the BMD level, the BM0 level, the BVG level and the BVD level. In some embodiments, at least layout design 200, or integrated circuit 300, 400A, 400B, 500 or 600 includes additional elements not shown in FIG. 2A-2B, 3A-3E, 5A-5B or 6A-6D. In some embodiments, layout design 200 further includes one or more features of the BM1 level or the BV0 level.

Layout design 200 is usable to manufacture integrated circuit 300 of FIGS. 3A-3E.

Portion 200A is a layout of portion 300A of integrated circuit 300 of FIG. 3A, and portion 200B is a layout of portion 300B of integrated circuit 300 of FIG. 3B, and similar detailed description is omitted for brevity.

Layout design 200 includes a cell 201. The cell 201 has cell boundaries 201a and 201b that extend in a first direction X, and cell boundaries 201c and 201d that extend in a second direction Y. In some embodiments, at least one of the first direction X, the second direction Y or a third direction Z is different from another of the first direction X, the second direction Y or the third direction Z. In some embodiments, layout design 200 abuts other cell layout designs (not shown) along cell boundaries 201c and 201d. In some embodiments, layout design 200 abuts other cell layout designs (not shown) along cell boundaries 201a and 201b that extend in the first direction X. In some embodiments, layout design 200 is a single height standard cell. In some embodiments, cell 201 is useable to manufacture a cell 301.

In some embodiments, cell 201 is a standard cell, and layout design 200 corresponds to a layout of a standard cell defined by cell boundaries 201a, 201b, 201c and 201d. In some embodiments, a cell 201 is a predefined portion of layout design 200 including one or more transistors and electrical connections configured to perform one or more circuit functions. In some embodiments, cell 201 is bounded by cell boundaries 201a, 201b, 201c and 201d, and thus corresponds to a region of functional circuit components or devices that are part of a standard cell. In some embodiments, layout design 200 is a layout design of a memory cell, such as memory cell 200A of FIG. 2A or 200B of FIG. 2B.

Layout design 200 includes active region layout pattern 202a (collectively referred to as a “set of active region patterns 202”) or active region layout pattern 204a (collectively referred to as a “set of active region patterns 204”) extending in the first direction X.

Embodiments of the present disclosure use the term “layout pattern” which is hereinafter also referred to as “patterns” in the remainder of the present disclosure for brevity.

The set of active region patterns 202 is above the set of active region patterns 204.

Each active region pattern of the set of active region patterns 202 is separated from one another in the second direction Y. Each active region pattern of the set of active region patterns 204 is separated from one another in the second direction Y.

Active region patterns 202a and 204a are separated from one another in a third direction Z.

The set of active region patterns 202 is usable to manufacture a corresponding set of active regions 302 of integrated circuit 100, 300, 400A, 400B, 500 or 600. The set of active region patterns 204 is usable to manufacture a corresponding set of active regions 304 of integrated circuit 100, 300, 400A, 400B, 500 or 600.

In some embodiments, at least one of the set of active regions 302 or 304 are located on the front-side 303a of integrated circuit 100, 300, 400A, 400B, 500 or 600. In some embodiments, at least one of the set of active regions 302 or 304 corresponds to source and drain regions of one or more complementary FET (CFET) transistors. In some embodiments, at least one of the set of active regions 302 or 304 correspond to source and drain regions of one or more nanosheet transistors or nanowire transistors. Other transistor types are within the scope of the present disclosure. In some embodiments, at least one of the set of active regions 302 or 304 corresponds to source and drain regions of one or more finFET transistors.

In some embodiments, active region pattern 202a is usable to manufacture corresponding active region 302a of the set of active regions 302 of integrated circuit 100, 300, 400A, 400B, 500 or 600. In some embodiments, active region pattern 204a is usable to manufacture corresponding active region 304a of the set of active regions 304 of integrated circuit 100, 300, 400A, 400B, 500 or 600.

In some embodiments, the set of active region patterns 202 and 204 are referred to as an oxide diffusion (OD) region which defines the source or drain diffusion regions of at least integrated circuit 100, 300, 400A, 400B, 500 or 600 or layout design 200.

In some embodiments, active region pattern 202a is usable to manufacture source and drain regions of NFET transistors of integrated circuits 100, 300, 400A, 400B, 500 or 600, and active region pattern 204a is usable to manufacture source and drain regions of PFET transistors of integrated circuits 100, 300, 400A, 400B, 500 or 600.

In some embodiments, active region pattern 202a is usable to manufacture source and drain regions of PFET transistors of integrated circuits 100, 300, 400A, 400B, 500 or 600, and active region pattern 204a is usable to manufacture source and drain regions of NFET transistors of integrated circuits 100, 300, 400A, 400B, 500 or 600.

In some embodiments, the set of active region patterns 202 or 204 is located on a first layout level. In some embodiments, the first layout level corresponds to an active level or an OD level of one or more of layout design 200 or integrated circuits 100, 300, 400A, 400B, 500 or 600. In some embodiments, the OD level is above the BM0 level and the BM1 level.

Other configurations, arrangements on other layout levels or quantities of patterns in the set of active region patterns 202 or 204 are within the scope of the present disclosure.

Layout design 200 further includes one or more gate patterns 206a, 206b, 206c, 206d, 206c, 206f, 206g, 206h, 206i or 206j (collectively referred to as a “set of gate patterns 206”), one or more gate patterns 208a, 208b, 208c, 208d, 208c, 208f, 208g, 208h, 208i or 208j (collectively referred to as a “set of gate patterns 208”) extending in the second direction Y.

The set of gate patterns 206 is above the set of gate patterns 208.

Each gate pattern in the set of gate patterns 206 is separated from one another in the first direction X. Each gate pattern in the set of gate patterns 208 is separated from one another in the first direction X.

In some embodiments, each gate pattern in the set of gate patterns 206 is separated from a corresponding gate pattern in the set of gate patterns 208 in the third direction Z.

The set of gate patterns 206 is usable to manufacture a corresponding set of gates 306 of integrated circuit 100, 300, 400A, 400B, 500 or 600. The set of gate patterns 208 is usable to manufacture a corresponding set of gates 308 of integrated circuit 100, 300, 400A, 400B, 500 or 600.

In some embodiments, gate patterns 206a, 206b, 206c, 206d, 206c, 206f, 206g, 206h, 206i or 206j are usable to manufacture corresponding gates 306a, 306b, 306c, 306d, 306c, 306f, 306g, 306h, 306i or 306j of the set of gates 306 of integrated circuit 100, 300, 400A, 400B, 500 or 600. In some embodiments, gate patterns 208a, 208b, 208c, 208d, 208c, 208f, 208g, 208h, 208i or 208j are usable to manufacture corresponding gates 308a, 308b, 308c, 308d, 308c, 308f, 308g, 308h, 308i or 308j of the set of gates 308 of integrated circuit 100, 300, 400A, 400B, 500 or 600.

In some embodiments, at least one of gate patterns 206a or 206j is a corresponding dummy gate pattern. In some embodiments, at least one of gate patterns 208a or 208j is a corresponding dummy gate pattern. In some embodiments, dummy gate patterns are also referred to as continuous poly over diffusion edge (CPODE) patterns. In some embodiments, at least one of gate patterns 206a or 206j overlaps corresponding cell boundaries 201c or 201d. In some embodiments, at least one of gate patterns 208a or 208j overlaps corresponding cell boundaries 201c or 201d. Other gate patterns configured as dummy gates are within the scope of the present disclosure.

In some embodiments, at least one of the set of gates 306 or 308 are located on the front-side 303a of integrated circuit 100, 300, 400A, 400B, 500 or 600.

In some embodiments, each of the gate patterns in the set of gate patterns 206 and 208 is shown in FIGS. 3A-3B with labels “P1-L, P2-L, P3-L, P4-L, P1-R, P2-R, P3-R, P4-R, N1-L, N2-L, N3-L, N4-L, N1-R, N2-R, N3-R AND N4-R.” that identify corresponding transistors of FIG. 1 manufactured by the corresponding gate pattern in FIGS. 2A-2B, and are omitted for brevity.

In some embodiments, the set of gate patterns 206 or 208 encapsulate the set of active region patterns 202 and 204. In some embodiments, a portion of the set of gate patterns 206 or 208 is above the set of active region patterns 202 and 204. In some embodiments, another portion of the set of gate patterns 206 or 208 is below the set of active region patterns 202 and 204.

The set of gate patterns 206 or 208 is positioned on a second layout level. In some embodiments, the second layout level is different from the first layout level. In some embodiments, the second layout level corresponds to the POLY level of one or more of layout design 200 or integrated circuits 100, 300, 400A, 400B, 500 or 600. In some embodiments, the POLY level is above the BMD level and the BM0 level.

Other configurations, arrangements on other layout levels or quantities of patterns in the set of gate patterns 206 or 208 are within the scope of the present disclosure.

Layout design 200 further includes one or more contact patterns 210a, 210b, 210c, 210d, 210c, 210f, 210g, 210h or 210i (collectively referred to as a “set of contact patterns 210”) extending in the second direction Y.

Each of the contact patterns of the set of contact patterns 210 is separated from an adjacent contact pattern of the set of contact patterns 210 in at least the first direction X.

The set of contact patterns 210 is usable to manufacture a corresponding set of contacts 310 of integrated circuit 100, 300, 400A, 400B, 500 or 600.

In some embodiments, contact pattern 210a, 210b, 210c, 210d, 210c, 210f, 210g, 210h or 210i of the set of contact patterns 210 is usable to manufacture corresponding contact 310a, 310b, 310c, 310d, 310c, 310f, 310g, 310h or 310i of the set of contacts 310. In some embodiments, the set of contact patterns 210 is also referred to as a set of metal over diffusion (MD) patterns.

In some embodiments, at least one of contact pattern 210a, 210b, 210c, 210d, 210c, 210f, 210g, 210h or 210i of the set of contact patterns 210 is usable to manufacture source or drain terminals of one of the NFET or PFET transistors of integrated circuit 100, 300, 400A, 400B, 500 or 600.

In some embodiments, contact pattern 210a is usable to manufacture drain terminals of NFET transistor N2-L, contact pattern 210c is usable to manufacture drain terminals of NFET transistor N1-L and NFET transistor N1-R, contact pattern 210e is usable to manufacture drain terminals of NFET transistor N2-R and NFET transistor N3-R, contact pattern 210g is usable to manufacture drain terminals of NFET transistor N4-R and NFET transistor N4-L, and contact pattern 210i is usable to manufacture drain terminals of NFET transistor N3-L.

In some embodiments, contact pattern 210b is usable to manufacture source terminals of NFET transistor N2-L and NFET transistor N1-L, contact pattern 210d is usable to manufacture source terminals of NFET transistor N1-R and NFET transistor N2-R, contact pattern 210f is usable to manufacture source terminals of NFET transistor N3-R and NFET transistor N4-R, and contact pattern 210h is usable to manufacture source terminals of NFET transistor N4-L and NFET transistor N3-L.

In some embodiments, the set of contact patterns 210 overlap the set of active region patterns 202 or 204. The set of contact patterns 210 is located on a third layout level. In some embodiments, the third layout level corresponds to the contact level or an MD level of one or more of layout design 200 or integrated circuits 100, 300, 400A, 400B, 500 or 600. In some embodiments, the third layout level is different from at least one of the first layout level or the second layout level. Other configurations, arrangements on other layout levels or quantities of patterns in the set of contact patterns 210 are within the scope of the present disclosure.

Layout design 200 further includes one or more contact patterns 212a, 212b, 212c, 212d, 212c, 212f, 212g, 212h or 212i (collectively referred to as a “set of contact patterns 212”) extending in the second direction Y.

Each of the contact patterns of the set of contact patterns 212 is separated from an adjacent contact pattern of the set of contact patterns 212 in at least the first direction X.

The set of contact patterns 210 and 212 are separated from one another in the third direction Z. In some embodiments, contact patterns 210a and 212a are separated from one another in the third direction Z. In some embodiments, contact patterns 210b and 212b are separated from one another in the third direction Z. In some embodiments, contact patterns 210d and 212d are separated from one another in the third direction Z. In some embodiments, contact patterns 210e and 212e are separated from one another in the third direction Z. In some embodiments, contact patterns 210f and 212f are separated from one another in the third direction Z. In some embodiments, contact patterns 210g and 212g are separated from one another in the third direction Z. In some embodiments, contact patterns 210h and 212h are separated from one another in the third direction Z. In some embodiments, contact patterns 210i and 212i are separated from one another in the third direction Z. In some embodiments, contact patterns 210c and 212c are separated from one another in the third direction Z.

The set of contact patterns 212 is usable to manufacture a corresponding set of contacts 312 of integrated circuit 100, 300, 400A, 400B, 500 or 600.

In some embodiments, contact pattern 212a, 212b, 212c, 212d, 212c, 212f, 212g, 212h or 212i of the set of contact patterns 212 is usable to manufacture corresponding contact 312a, 312b, 312c, 312d, 312c, 312f, 312g, 312h or 312i of the set of contacts 312. In some embodiments, the set of contacts 312 are on a front-side 303a of integrated circuit 300. In some embodiments, a back-side 303b of integrated circuit 300 is opposite from the front-side of integrated circuit 300. In some embodiments, the set of contacts patterns 212 is also referred to as a set of back-side MD (BMD) patterns.

In some embodiments, at least one of contact pattern 212a, 212b, 212c, 212d, 212c, 212f, 212g, 212h or 212i of the set of contact patterns 212 is usable to manufacture source or drain terminals of one of the NFET or PFET transistors of integrated circuit 100, 300, 400A, 400B, 500 or 600.

In some embodiments, contact pattern 212a is usable to manufacture source terminals of PFET transistor P2-L, contact pattern 212b is usable to manufacture drain terminals of PFET transistor P2-L and source terminals of PFET transistor P1-L, contact pattern 212c is usable to manufacture drain terminals of PFET transistor P1-L and drain terminals of PFET transistor P1-R, contact pattern 212d is usable to manufacture source terminals of PFET transistor P1-R and drain terminals of PFET transistor P2-R, contact pattern 212e is usable to manufacture source terminals of PFET transistor P2-R and drain terminals of PFET transistor P3-R, contact pattern 212f is usable to manufacture source terminals of PFET transistor P3-R and drain terminals of PFET transistor P4-R, contact pattern 212g is usable to manufacture source terminals of PFET transistor P4-R and source terminals of PFET transistor P4-L, contact pattern 212h is usable to manufacture drain terminals of PFET transistor P4-L and source terminals of PFET transistor P3-L, and contact pattern 212i is usable to manufacture drain terminals of PFET transistor P3-L.

In some embodiments, the set of contact patterns 212 are overlapped by the set of active region patterns 202 or 204. The set of contact patterns 212 is located on a fourth layout level. In some embodiments, the fourth layout level corresponds to the back-side contact level or a back-side MD (BMD) level of one or more of layout design 200 or integrated circuits 100, 300, 400A, 400B, 500 or 600. In some embodiments, the fourth layout level is different from at least one of the first layout level, the second layout level or the third layout level.

In some embodiments, the BMD level is above the BM0 level. In some embodiments, the BMD level is above the back-side 303b of integrated circuit 300. In some embodiments, the BMD level is below the OD level, the POLY level, the MD level and the M0 level.

Other configurations, arrangements on other layout levels or quantities of patterns in the set of contact patterns 212 are within the scope of the present disclosure.

Layout design 200 further includes contact pattern 214a (collectively referred to as a “set of contact patterns 214”) extending in the second direction Y.

Each of the contact patterns of the set of contact patterns 214 is separated from an adjacent contact pattern of the set of contact patterns 214 in at least the first direction X or the second direction Y.

In some embodiments, the set of contact patterns 214 is between the set of contact patterns 210 and 212. Contact pattern 214a is between contact patterns 210c and 212c.

In some embodiments, contact pattern 214a includes one or more separate discontinuous patterns.

The set of contact patterns 214 is usable to manufacture a corresponding set of contacts 314 of integrated circuit 100, 300, 400A, 400B, 500 or 600.

In some embodiments, contact pattern 214a of the set of contact patterns 214 is usable to manufacture corresponding contact 314a of the set of contacts 314. In some embodiments, the set of contacts 314 are on a front-side 303a of integrated circuit 300. In some embodiments, the set of contacts patterns 214 is also referred to as a set of local interconnect (MDLI) patterns.

In some embodiments, at least one of contact pattern 214a of the set of contact patterns 214 is usable to manufacture interconnect structures usable to connect source or drain terminals of one of the NFET or PFET transistors of integrated circuit 100, 300, 400A, 400B, 500 or 600.

In some embodiments, contact pattern 214a is usable to manufacture drain terminals of NFET transistor N1-L, drain terminals of NFET transistor N1-R, drain terminals of PFET transistor P1-L and drain terminals of PFET transistor P1-R.

In some embodiments, at least a first portion of the set of contact patterns 214 are overlapped by one or more of the set of active region patterns 202 or 204. In some embodiments, at least a second portion of the set of contact patterns 214 is between the set of active region patterns 202 or 204. In some embodiments, at least a third portion of the set of contact patterns 214 is coplanar with the set of contact patterns 210 or the set of contact patterns 212.

The set of contact patterns 214 is located on a fifth layout level. In some embodiments, the fifth layout level corresponds to the MDLI level of one or more of layout design 200 or integrated circuits 100, 300, 400A, 400B, 500 or 600. In some embodiments, the fifth layout level is different from at least one of the first layout level or the second layout level.

In some embodiments, the MDLI level includes the MD level and the BMD level. In some embodiments, the MDLI level is below the M0 level. In some embodiments, the MDLI level is above the BM0 level.

Other configurations, arrangements on other layout levels or quantities of patterns in the set of contact patterns 214 are within the scope of the present disclosure.

Layout design 200 further includes one or more conductive feature patterns 230a, 230b, 230c, 230d, 230e (collectively referred to as a “set of conductive feature patterns 230”) extending in the first direction X.

Each conductive feature pattern in the set of conductive feature patterns 230 is separated from another conductive feature pattern in the set of conductive feature patterns 230 in the first direction X or the second direction Y.

The set of conductive feature patterns 230 overlap at least one of the set of active region patterns 202 or 204, the set of gate patterns 206 or 208 or the set of contact patterns 210, 212 or 214.

The set of conductive feature patterns 230 is usable to manufacture a corresponding set of conductors 330 of integrated circuit 100, 300, 400A, 400B, 500 or 600. Conductive feature patterns 230a, 230b, 230c, 230d, 230e are usable to manufacture corresponding conductors 330a, 330b, 330c, 330d, 330c of integrated circuit 100, 300, 400A, 400B, 500 or 600. In some embodiments, at least one conductor of the set of conductors 330 is located on the front-side 303a of integrated circuit 100, 300, 400A, 400B, 500 or 600.

In some embodiments, the set of conductive feature patterns 230 is located on a sixth layout level. In some embodiments, the sixth layout level is different from at least one of the first layout level, the second layout level, the third layout level, the fourth layout level or the fifth layout level. In some embodiments, the sixth layout level corresponds to the M0 level of one or more of layout design 200 or integrated circuits 100, 300, 400A, 400B, 500 or 600. In some embodiments, the M0 level is above the OD level, the POLY level, the MD level, the BMD level and the BM0 level.

In some embodiments, the set of conductive feature patterns 230 correspond to 2 M0 routing tracks. Other numbers of M0 routing tracks are within the scope of the present disclosure.

Other configurations, arrangements on other layout levels or quantities of patterns in the set of conductive feature patterns 230 are within the scope of the present disclosure.

Other M0 track assignments are within the scope of the present disclosure.

Layout design 200 further includes one or more conductive feature patterns 232a, 232b, 232c (collectively referred to as a “set of conductive feature patterns 232”) extending in the first direction X.

Each conductive feature pattern in the set of conductive feature patterns 232 is separated from another conductive feature pattern in the set of conductive feature patterns 232 in the first direction X or the second direction Y.

The set of conductive feature patterns 232 is overlapped by at least one of the set of active region patterns 202 or 204, the set of gate patterns 206 or 208 or the set of contact patterns 210, 212 or 214.

The set of conductive feature patterns 230 and 232 are separated from one another in the third direction Z. In some embodiments, conductive feature patterns 230e and 232a are separated from one another in the third direction Z.

The set of conductive feature patterns 232 is usable to manufacture a corresponding set of conductors 332 of integrated circuit 100, 300, 400A, 400B, 500 or 600. Conductive feature patterns 232a, 232b, 232c are usable to manufacture corresponding conductors 332a, 332b, 332c of integrated circuit 100, 300, 400A, 400B, 500 or 600. In some embodiments, at least one conductor of the set of conductors 332 is located on the back-side 303b of integrated circuit 100, 300, 400A, 400B, 500 or 600.

In some embodiments, the set of conductive feature patterns 232 is located on a seventh layout level. In some embodiments, the seventh layout level is different from at least one of the first layout level, the second layout level, the third layout level, the fourth layout level, the fifth layout level or the sixth layout level. In some embodiments, the seventh layout level corresponds to the BM0 level of one or more of layout design 200 or integrated circuits 100, 300, 400A, 400B, 500 or 600. In some embodiments, the BM0 level is below the OD level, the POLY level, the MD level, the BMD level and the BM1 level.

In some embodiments, the set of conductive feature patterns 232 corresponds to 2 BM0 routing tracks. Other numbers of BM0 routing tracks are within the scope of the present disclosure. Other BM0 track assignments are within the scope of the present disclosure.

Other configurations, arrangements on other layout levels or quantities of patterns in the set of conductive feature patterns 232 are within the scope of the present disclosure.

Layout design 200 further includes one or more power rail feature patterns 236a, 236b (collectively referred to as a “set of power rail patterns 236”) extending in the first direction X.

Each power rail pattern in the set of power rail patterns 236 is separated from another power rail pattern in the set of power rail patterns 236 in the first direction X or the second direction Y.

The set of power rail patterns 236 overlap at least one of the set of active region patterns 202 or 204, the set of gate patterns 206 or 208 or the set of contact patterns 210, 212 or 214.

The set of power rail patterns 236 is usable to manufacture a corresponding set of power rails 336 of integrated circuit 100, 300, 400A, 400B, 500 or 600. Power rail patterns 236a, 236b are usable to manufacture corresponding power rails 336a, 336b of integrated circuit 100, 300, 400A, 400B, 500 or 600.

In some embodiments, power rail 336a of the set of power rails 336 is located on the front-side 303a of integrated circuit 100, 300, 400A, 400B, 500 or 600. In some embodiments, power rail 336b of the set of power rails 336 is located on the back-side 303b of integrated circuit 100, 300, 400A, 400B, 500 or 600.

In some embodiments, the set of power rail patterns 236 is located on the sixth layout level or the seventh layout level. In some embodiments, power rail pattern 236a of the set of power rail patterns 236 is located on the sixth layout level. In some embodiments, power rail pattern 236b of the set of power rail patterns 236 is located on the seventh layout level.

Other configurations, arrangements on other layout levels or quantities of patterns in the set of power rail patterns 236 are within the scope of the present disclosure.

Layout design 200 further includes one or more via patterns 220a, 220b, 220c, 220d (collectively referred to as a “set of via patterns 220”).

The set of via patterns 220 is usable to manufacture a corresponding set of vias 320 of integrated circuit 100, 300, 400A, 400B, 500 or 600. In some embodiments, via patterns 220a, 220b, 220c, 220d, 220e of the set of via patterns 220 are usable to manufacture corresponding vias 320a, 320b, 320c, 320d, 320e of the set of vias 320 of integrated circuit 100, 300, 400A, 400B, 500 or 600.

In some embodiments, the set of via patterns 220 is between at least the set of contact patterns 210 or 214 and the set of conductive feature patterns 230. Via pattern 220a is between contact pattern 210a and conductive feature pattern 230e. Via pattern 220b is between at least contact pattern 210c or 214a and conductive feature pattern 230e. Via pattern 220c is between contact pattern 210e and conductive feature pattern 230e. Via pattern 220d is between contact pattern 210g and conductive feature pattern 230e. Via pattern 220e is between contact pattern 210i and conductive feature pattern 230c.

The set of via patterns 220 is positioned at a via over diffusion (VD) level of one or more of layout design 200 or integrated circuits 100, 300, 400A, 400B, 500 or 600. In some embodiments, the VD level is above the OD level, the POLY level, the MD level, the BMD level and the BM0 level. In some embodiments, the VD level is below the M0 level. In some embodiments, the VD level is between the MD level and the M0 level. In some embodiments, the VD level is between at least the third layout level or the fifth layout level and the sixth layout level. Other layout levels are within the scope of the present disclosure.

Other configurations, arrangements on other layout levels or quantities of patterns in at least set of via patterns 220 are within the scope of the present disclosure.

Layout design 200 further includes one or more via patterns 222a, 222b (collectively referred to as a “set of via patterns 222”).

The set of via patterns 222 is usable to manufacture a corresponding set of vias 322 of integrated circuit 100, 300, 400A, 400B, 500 or 600. In some embodiments, via patterns 222a, 222b of the set of via patterns 222 are usable to manufacture corresponding vias 322a, 322b of the set of vias 322 of integrated circuit 100, 300, 400A, 400B, 500 or 600.

In some embodiments, the set of via patterns 222 is between at least the set of contact patterns 212 or 214 and the set of conductive feature patterns 232. Via pattern 222a is between contact pattern 212a and conductive feature pattern 232a. Via pattern 222b is between contact pattern 212i and conductive feature pattern 232a.

The set of via patterns 222 is positioned at a back-side via over diffusion (BVD) level of one or more of layout design 200 or integrated circuits 100, 300, 400A, 400B, 500 or 600. In some embodiments, the BVD level is below the OD level, the POLY level, the MD level, the BMD level and the M0 level. In some embodiments, the BVD level is above the BM0 level and the BM1 level. In some embodiments, the BVD level is between the BMD level and the BM0 level. In some embodiments, the BVD level is between at least the fourth layout level or the fifth layout level and the seventh layout level. Other layout levels are within the scope of the present disclosure.

Other configurations, arrangements on other layout levels or quantities of patterns in at least set of via patterns 222 are within the scope of the present disclosure.

Layout design 200 further includes one or more via patterns 224a, 224b, 224c, 224d, 224c, 224f (collectively referred to as a “set of via patterns 224”).

The set of via patterns 224 is usable to manufacture a corresponding set of vias 324 of integrated circuit 100, 300, 400A, 400B, 500 or 600. In some embodiments, via patterns 224a, 224b, 224c, 224d, 224c, 224f of the set of via patterns 224 are usable to manufacture corresponding vias 324a, 324b, 324c, 324d, 324c, 324f of the set of vias 324 of integrated circuit 100, 300, 400A, 400B, 500 or 600.

In some embodiments, the set of via patterns 224 is between the set of gate patterns 206 and the set of conductive feature patterns 230. Via pattern 224a is between gate pattern 206b and conductive feature pattern 230a. Via pattern 224b is between gate pattern 206c and conductive feature pattern 230b. Via pattern 224c is between gate pattern 206d and conductive feature pattern 230b. Via pattern 224d is between gate pattern 206g and conductive feature pattern 230c. Via pattern 224c is between gate pattern 206h and conductive feature pattern 230c. Via pattern 224f is between gate pattern 206i and conductive feature pattern 230d.

The set of via patterns 224 is positioned at a via over gate (VG) level of one or more of layout design 200 or integrated circuits 100, 300, 400A, 400B, 500 or 600. In some embodiments, the VG level is above the OD level, the POLY level, the MD level, the MDLI level, the BMD level, the BM0 level and the BM1 level. In some embodiments, the VG level is below the M0 level and the M1 level. In some embodiments, the VG level is between the POLY level and the M0 level. In some embodiments, the VG level is between the second layout level and the sixth layout level. Other layout levels are within the scope of the present disclosure.

Other configurations, arrangements on other layout levels or quantities of patterns in at least set of via patterns 224 are within the scope of the present disclosure.

Layout design 200 further includes one or more via patterns 226a, 226b, 226c, 226d (collectively referred to as a “set of via patterns 226”).

The set of via patterns 226 is usable to manufacture a corresponding set of vias 326 of integrated circuit 100, 300, 400A, 400B, 500 or 600. In some embodiments, via patterns 226a, 226b, 226c, 226d of the set of via patterns 226 are usable to manufacture corresponding vias 326a, 326b, 326c, 326d of the set of vias 326 of integrated circuit 100, 300, 400A, 400B, 500 or 600.

In some embodiments, the set of via patterns 226 is between the set of gate patterns 208 and the set of conductive feature patterns 232. Via pattern 226a is between gate pattern 208b and conductive feature pattern 232b. Via pattern 226b is between gate pattern 208e and conductive feature pattern 232b. Via pattern 226c is between gate pattern 208f and conductive feature pattern 232c. Via pattern 226d is between gate pattern 208i and conductive feature pattern 232c.

The set of via patterns 226 is positioned at a back-side via over gate (BVG) level of one or more of layout design 200 or integrated circuits 100, 300, 400A, 400B, 500 or 600. In some embodiments, the BVG level is below the OD level, the POLY level, the MD level, the MDLI level, the BMD level, the M0 level and the M1 level. In some embodiments, the BVG level is above the BM0 level and the BM1 level. In some embodiments, the BVG level is between the POLY level and the BM0 level. In some embodiments, the BVG level is between the second layout level and the seventh layout level. Other layout levels are within the scope of the present disclosure.

Other configurations, arrangements on other layout levels or quantities of patterns in at least set of via patterns 226 are within the scope of the present disclosure.

Layout design 200 further includes one or more conductive feature patterns 250a, 250b, 250c, 250d, 250c (collectively referred to as a “set of conductive feature patterns 250”) extending in the second direction Y.

Each conductive feature pattern in the set of conductive feature patterns 250 is separated from another conductive feature pattern in the set of conductive feature patterns 250 in the first direction X.

The set of conductive feature patterns 250 overlap at least one of the set of active region patterns 202 or 204, the set of gate patterns 206 or 208 or the set of contact patterns 210, 212 or 214 or the set of conductive feature patterns 230 or 232.

The set of conductive feature patterns 250 is usable to manufacture a corresponding set of conductors 350 of integrated circuit 100, 300, 400A, 400B, 500 or 600. Conductive feature patterns 250a, 250b, 250c, 250d, 250e are usable to manufacture corresponding conductors 350a, 350b, 350c, 350d, 350c of integrated circuit 100, 300, 400A, 400B, 500 or 600. In some embodiments, at least one conductor of the set of conductors 350 is located on the front-side 303a of integrated circuit 100, 300, 400A, 400B, 500 or 600.

In some embodiments, the set of conductive feature patterns 250 is located on an eighth layout level. In some embodiments, the eighth layout level is different from at least one of the first layout level, the second layout level, the third layout level, the fourth layout level, the fifth layout level, the sixth layout level or the seventh layout level. In some embodiments, the eighth layout level corresponds to the M1 level of one or more of layout design 200 or integrated circuits 100, 300, 400A, 400B, 500 or 600. In some embodiments, the M1 level is above the OD level, the POLY level, the MD level, the M0 level, the BMD level, the BM0 level and the BM1 level.

In some embodiments, the set of conductive feature patterns 250 corresponds to 5 M1 routing tracks. Other numbers of M1 routing tracks are within the scope of the present disclosure.

Other configurations, arrangements on other layout levels or quantities of patterns in the set of conductive feature patterns 250 are within the scope of the present disclosure.

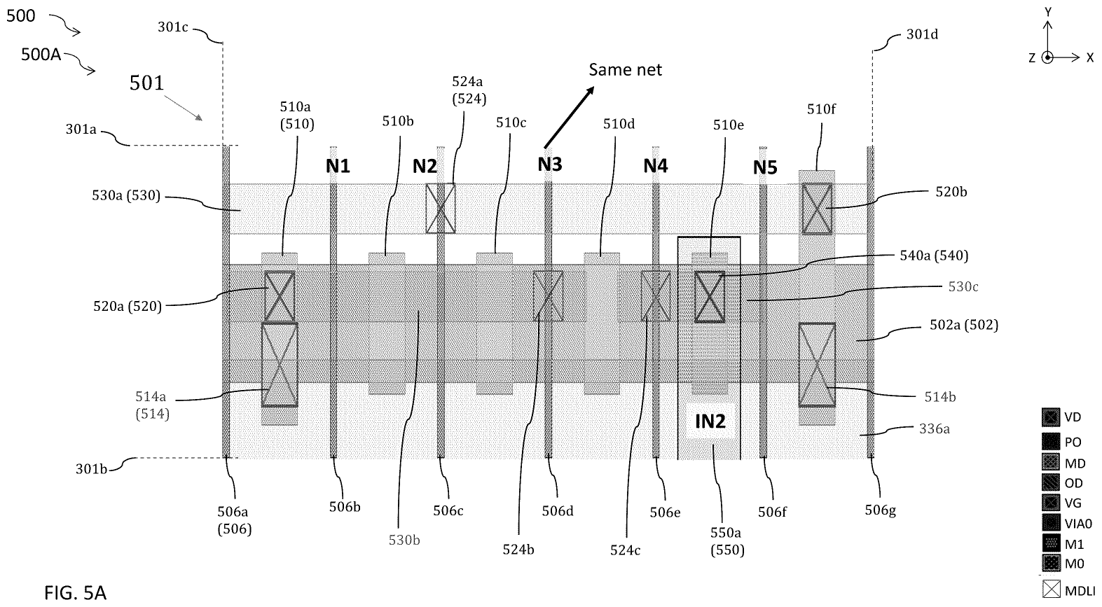

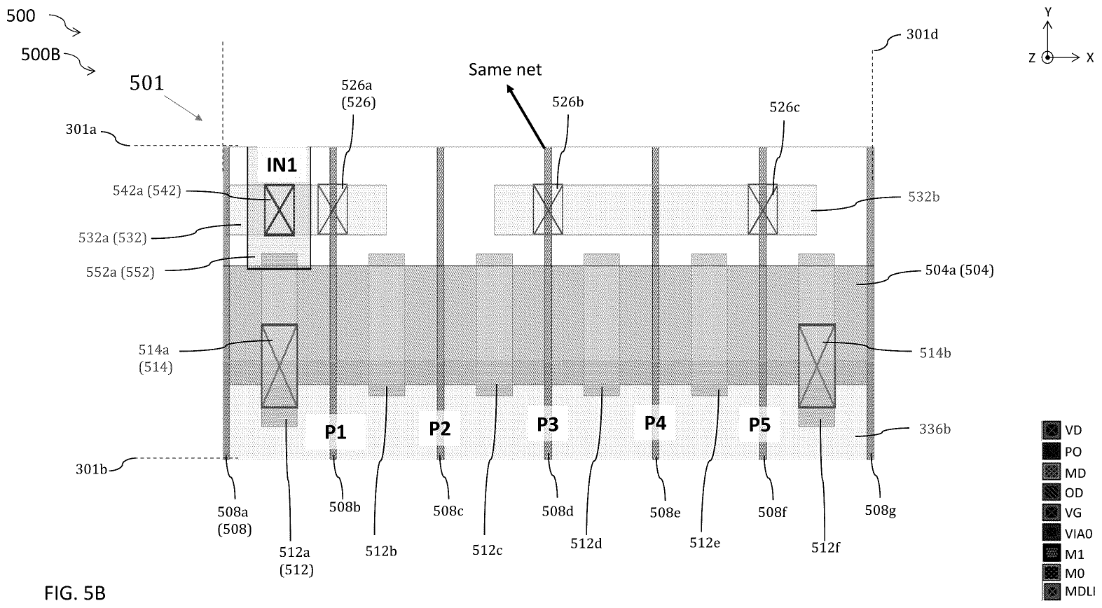

In some embodiments, layout design 200 further includes one or more conductive feature patterns similar to the set of conductors 552 (FIG. 5B) extending in the second direction Y.

Each conductive feature pattern similar to a conductor 552a in the set of conductors 552 is separated from another conductive feature pattern similar to the set of conductors 552 in the first direction X.

The set of conductive feature patterns similar to the set of conductors 552 is overlapped by at least one of the set of active region patterns 202 or 204, the set of gate patterns 206 or 208 or the set of contact patterns 210, 212 or 214, the set of conductive feature patterns 230 or 232 or set of conductive feature patterns 250.

The set of conductive feature patterns similar to the set of conductors 552 is usable to manufacture a corresponding set of conductors that is similar to the set of conductors 552 of integrated circuit 300.

In some embodiments, the set of conductive feature patterns similar to the set of conductors 552 is located on a ninth layout level. In some embodiments, the ninth layout level is different from at least one of the first layout level, the second layout level, the third layout level, the fourth layout level, the fifth layout level, the sixth layout level, the seventh layout level or the eighth layout level. In some embodiments, the ninth layout level corresponds to the BM1 level of one or more of layout design 200 or integrated circuits 100, 300, 400A, 400B, 500 or 600. In some embodiments, the BM1 level is below the OD level, the POLY level, the MD level, the BMD level, and the BM0 level.

Other configurations, arrangements on other layout levels or quantities of patterns in the set of conductive feature patterns that is similar to the set of conductors 552 are within the scope of the present disclosure.

Layout design 200 further includes one or more via patterns 240a, 240b, 240c, 240d, 240c (collectively referred to as a “set of via patterns 240”).

The set of via patterns 240 is usable to manufacture a corresponding set of vias 340 of integrated circuit 100, 300, 400A, 400B, 500 or 600. In some embodiments, via patterns 240a, 240b, 240c, 240d, 240c of the set of via patterns 240 are usable to manufacture corresponding vias 340a, 340b, 340c, 340d, 340c of the set of vias 340 of integrated circuit 100, 300, 400A, 400B, 500 or 600.

In some embodiments, the set of via patterns 240 is between the set of conductive feature patterns 230 and the set of conductive feature patterns 250. Via pattern 240a is between conductive feature pattern 230a and conductive feature pattern 250a. Via pattern 240b is between conductive feature pattern 230b and conductive feature pattern 250b. Via pattern 240c is between conductive feature pattern 230e and conductive feature pattern 250c. Via pattern 240d is between conductive feature pattern 230c and conductive feature pattern 250d. Via pattern 240e is between conductive feature pattern 230d and conductive feature pattern 250c.

The set of via patterns 240 is positioned at a via over M0 (V0) level of one or more of layout design 200 or integrated circuits 100, 300, 400A, 400B, 500 or 600. In some embodiments, the V0 level is above the OD level, the POLY level, the MD level, the M0 level, the BMD level, the BM0 level and the BM1 level. In some embodiments, the V0 level is below the M1 level. In some embodiments, the V0 level is between the M0 level and the M1 level. In some embodiments, the V0 level is between the sixth layout level and the eighth layout level. Other layout levels are within the scope of the present disclosure.

Other configurations, arrangements on other layout levels or quantities of patterns in at least set of via patterns 240 are within the scope of the present disclosure.

In some embodiments, layout design 200 further includes one or more via patterns similar to a set of vias 542 (FIG. 5B).

In some embodiments, the set of via patterns that is similar to the set of vias 542 is between the set of conductive feature patterns 232 and the set of conductive feature patterns that is similar to the set of conductors 552.

The set of via patterns that is similar to the set of vias 542 is positioned at a via over BM0 (BV0) level of one or more of layout design 200 or integrated circuits 100, 300, 400A, 400B, 500 or 600. In some embodiments, the BV0 level is below the OD level, the POLY level, the MD level, the M0 level, the M1 level, the BMD level, and the BM0 level. In some embodiments, the BV0 level is above the BM1 level. In some embodiments, the BV0 level is between the BM0 level and the BM1 level. In some embodiments, the BV0 level is between the seventh layout level and the ninth layout level. Other layout levels are within the scope of the present disclosure.

Other configurations, arrangements on other layout levels or quantities of patterns in at least set of via patterns that is similar to the set of vias 542 are within the scope of the present disclosure.

In some embodiments, by positioning via patterns 224a and 226a between corresponding conductive feature patterns 230a and 232b and corresponding gate patterns 206b and 208b, layout design 200 is useable to manufacture integrated circuit 300 where the frontside and the backside of integrated circuit 300 can be electrically connected together, and the set of conductive feature patterns 232 can be utilized as additional routing resources on the BM0 metallization levels thereby resulting in layout design 200 having at least one of a reduced pitch, a smaller area or a smaller standard cell than other approaches.

In some embodiments, by positioning via patterns 224f and 226d between corresponding conductive feature patterns 230d and 232c and corresponding gate patterns 206i and 208i, layout design 200 is useable to manufacture integrated circuit 300 where the frontside and the backside of integrated circuit 300 can be electrically connected together, and the set of conductive feature patterns 232 can be utilized as additional routing resources on the BM0 metallization levels thereby resulting in layout design 200 having at least one of a reduced pitch, a smaller area or a smaller standard cell than other approaches.

Other configurations, arrangements on other layout levels or quantities of patterns in layout design 200 are within the scope of the present disclosure.

FIGS. 3A-3E are diagrams of an integrated circuit 300, in accordance with some embodiments.

FIGS. 3A-3B are corresponding diagrams of corresponding portions 300A-300B of an integrated circuit 300, simplified for case of illustration.

Portion 300A includes one or more features of integrated circuit 300 of the OD level, the POLY level, the MD level, the MDLI level, the M0 level, the M1 level, the VG level, the VD level and the V0 level. Portion 300A is manufactured by portion 200A.

Portion 300B includes one or more features of integrated circuit 300 of the OD level, the POLY level, the BMD level, the MDLI level, the BM0 level, the BVG level, and the BVD level. Portion 300B is manufactured by portion 200B. In some embodiments, portion 300B further includes one or more features of integrated circuit 300 of the BM1 or the BV0 level.

FIGS. 3C-3E are corresponding cross-sectional views of integrated circuit 300, in accordance with some embodiments. FIG. 3C is a cross-sectional view of integrated circuit 300 as intersected by plane A-A′, in accordance with some embodiments. FIG. 3D is a cross-sectional view of integrated circuit 300 as intersected by plane B-B′, in accordance with some embodiments. FIG. 3E is a cross-sectional view of integrated circuit 300 as intersected by plane C-C′, in accordance with some embodiments.

Components that are the same or similar to those in one or more of FIGS. 1, 2A-2B, 3A-3E, 4A-4B, 5A-5B and 6A-6D are given the same reference numbers, and detailed description thereof is thus omitted.

Integrated circuit 300 is manufactured by layout design 200. Integrated circuit 300 is cell 301. Structural relationships including alignment, lengths and widths, as well as configurations and layers of integrated circuit 300, 500 and 600 are similar to the structural relationships and configurations and layers of layout design 200 of FIGS. 2A-2B, and similar detailed description will not be described in at least FIGS. 3A-3E, for brevity. For example, in some embodiments, at least one or more widths, lengths or pitches of layout design 200 is similar to corresponding widths, lengths or pitches of integrated circuit 300, 500 and 600, and similar detailed description is omitted for brevity. For example, in some embodiments, at least cell boundary 201a or 201b is similar to at least corresponding cell boundary 301a or 301b of integrated circuit 300, and similar detailed description is omitted for brevity.

Integrated circuit 300 includes at least the set of active regions 302 and 304, the set of gates 306 and 308, the set of contacts 310, the set of contacts 312, the set of contacts 314, the set of conductors 330, the set of conductors 332, the set of power rails 336, the set of vias 320, the set of vias 322, the set of vias 324, the set of vias 326, the set of conductors 350, the set of vias 340, a substrate 390, and an insulating region 392.

The set of active regions 302 and 304 are embedded in substrate 390. Substrate 390 has a front-side 303a and a back-side 303b opposite from the front-side 303a. In some embodiments, at least the set of active regions 302 and 304, the set of gates 306 and 308 or the set of contacts 310, 312 and 314 are formed in the front-side 303a of substrate 390.

In some embodiments, the set of active regions 302 and 304 correspond to active regions of CFET transistors. In some embodiments, the set of active regions 302 and 304 correspond to nanosheet structures (not labelled) of nanosheet transistors. In some embodiments, the set of active regions 302 or 304 include drain regions and source regions grown by an epitaxial growth process. In some embodiments, the set of active regions 302 or 304 include drain regions and source regions that are grown with an epitaxial material at the corresponding drain regions and source regions.

Other transistor types are within the scope of the present disclosure. For example, in some embodiments, the set of active regions 302 or 304 corresponds to nanowire structures (not shown) of nanowire transistors. In some embodiments, the set of active regions 302 or 304 corresponds to planar structures (not shown) of planar transistors. In some embodiments, the set of active regions 302 or 304 corresponds to fin structures (not shown) of finFETs.

In some embodiments, active region 302a corresponds to source and drain regions of NFET transistors of integrated circuit 100, 300, 400A, 400B, 500 or 600, and active region 304a corresponds to source and drain regions of PFET transistors of integrated circuit 100, 300, 400A, 400B, 500 or 600.

In some embodiments, active region 302a corresponds to source and drain regions of PFET transistors of integrated circuit 100, 300, 400A, 400B, 500 or 600, and active region 304a corresponds to source and drain regions of NFET transistors of integrated circuit 100, 300, 400A, 400B, 500 or 600.

In some embodiments, at least active region 302a is an N-type doped S/D region, and at least active region 304a is a P-type doped S/D region embedded in a dielectric material of substrate 390. In some embodiments, at least active region 302a is a P-type doped S/D region, and at least active region 304a is an N-type doped S/D region embedded in a dielectric material of substrate 390.

Other configurations, arrangements on other layout levels or quantities of structures in the set of active regions 302 or 304 are within the scope of the present disclosure.

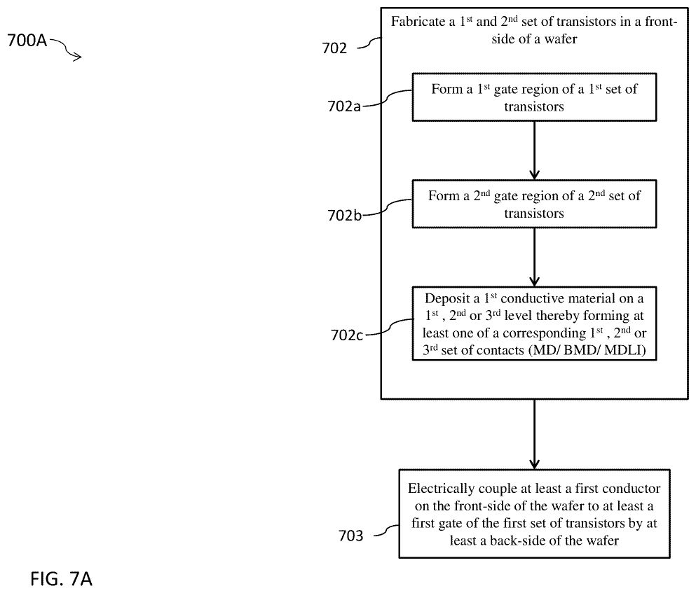

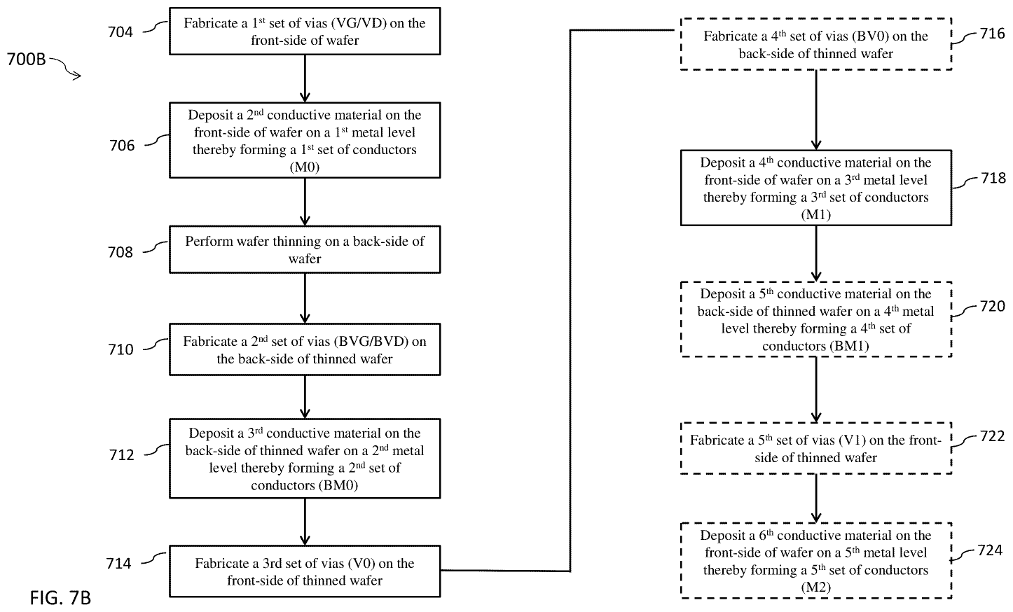

Insulating region 392 is configured to electrically isolate one or more elements of the set of active regions 302 and 304, the set of gates 306 and 308, the set of contacts 310, the set of contacts 312, the set of contacts 314, the set of conductors 330, the set of conductors 332, the set of power rails 336, the set of vias 320, the set of vias 322, the set of vias 324, the set of vias 326, the set of conductors 350 and the set of vias 340 from one another. In some embodiments, insulating region 392 includes multiple insulating regions deposited at different times from each other during method 700A-700B (FIGS. 7A-7B). In some embodiments, insulating region 392 is a dielectric material. In some embodiments, the dielectric material includes silicon dioxide, silicon oxy-nitride, or the like.

Other configurations, arrangements on other layout levels or other numbers of portions in insulating region 392 are within the scope of the present disclosure.

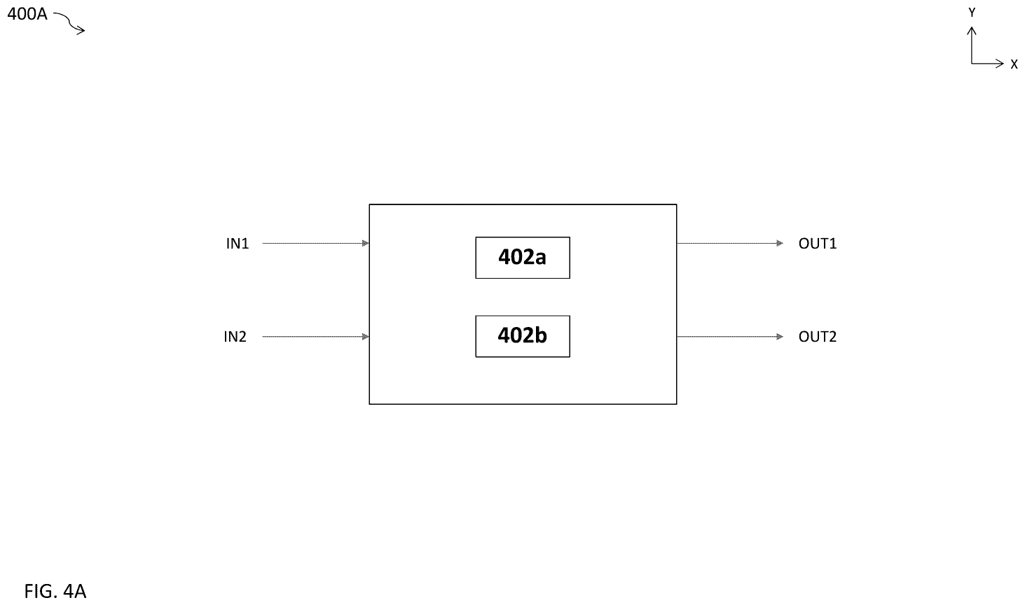

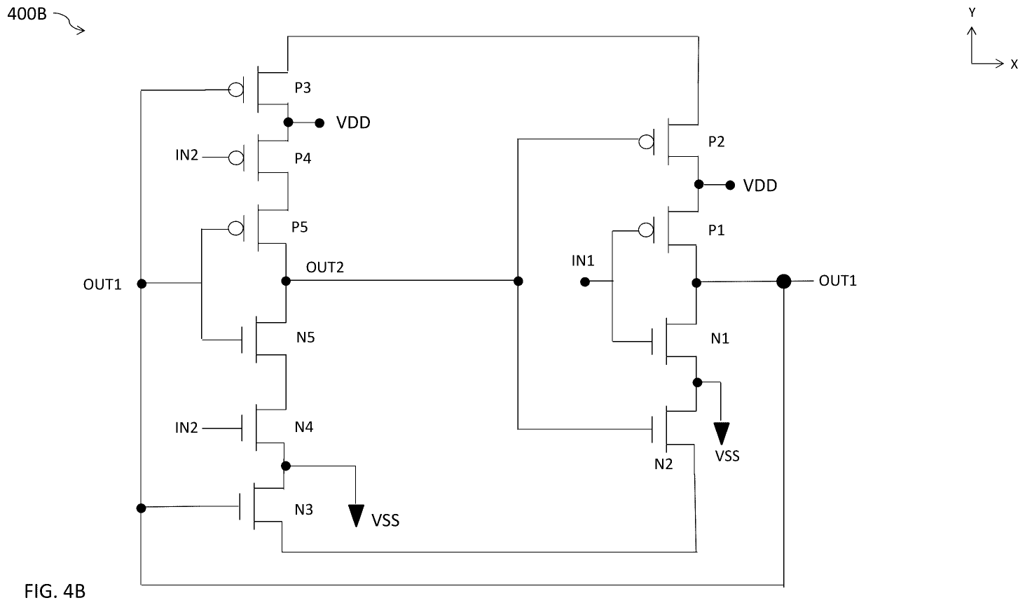

The set of gates 306 and 308 correspond to one or more gates of transistors P1-L, P2-L, P3-L, P4-L, P1-R, P2-R, P3-R, P4-R, N1-L, N2-L, N3-L, N4-L, N1-R, N2-R, N3-R and N4-R of integrated circuits 100, 300, 400A, 400B, 500 or 600. In some embodiments, each of the gates in the set of gates 306 and 308 are shown in FIGS. 4A-4F with labels “P1-L, P2-L, P3-L, P4-L, P1-R, P2-R, P3-R, P4-R, N1-L, N2-L, N3-L, N4-L, N1-R, N2-R, N3-R and N4-R” that identify corresponding transistors of FIGS. 2A-2B having corresponding gates in FIGS. 3A-3E, and are omitted for brevity.

In some embodiments, gate 306b is a gate of NFET transistor N2-L, gate 306c is a gate of NFET transistor N1-L, gate 306d is a gate of NFET transistor N1-R, gate 306e is a gate of NFET transistor N2-R, gate 306f is a gate of NFET transistor N3-R, gate 306g is a gate of NFET transistor N4-R, gate 306h is a gate of NFET transistor N4-L, and gate 306i is a gate of NFET transistor N3-L.

In some embodiments, gate 306a is a dummy gate of a dummy transistor. In some embodiments, a dummy transistor is a non-functional transistor. In some embodiments, gate 306j is a dummy gate of a dummy transistor.

In some embodiments, gate 308b is a gate of PFET transistor P2-L, gate 308c is a gate of PFET transistor P1-L, gate 308d is a gate of PFET transistor P1-R, gate 308e is a gate of PFET transistor P2-R, gate 308f is a gate of PFET transistor P3-R, gate 308g is a gate of PFET transistor P4-R, gate 308h is a gate of PFET transistor P4-L, and gate 308i is a gate of PFET transistor P3-L.

In some embodiments, gate 308a is a dummy gate of a dummy transistor. In some embodiments, gate 308j is a dummy gate of a dummy transistor.

In some embodiments, gate 306a and gate 308a are coupled together. In some embodiments, gate 306a and gate 308a are part of the same continuous structure.

In some embodiments, gate 306b and gate 308b are coupled together. In some embodiments, gate 306b and gate 308b are part of the same continuous structure.

In some embodiments, gate 306c and gate 308c are coupled together. In some embodiments, gate 306c and gate 308c are part of the same continuous structure.

In some embodiments, gate 306d and gate 308d are coupled together. In some embodiments, gate 306d and gate 308d are part of the same continuous structure.

In some embodiments, gate 306e and gate 308e are coupled together. In some embodiments, gate 306e and gate 308e are part of the same continuous structure.

In some embodiments, gate 306f and gate 308f are coupled together. In some embodiments, gate 306f and gate 308f are part of the same continuous structure.

In some embodiments, gate 306g and gate 308g are coupled together. In some embodiments, gate 306g and gate 308g are part of the same continuous structure.

In some embodiments, gate 306h and gate 308h are coupled together. In some embodiments, gate 306h and gate 308h are part of the same continuous structure.

In some embodiments, gate 306i and gate 308i are coupled together. In some embodiments, gate 306i and gate 308i are part of the same continuous structure.

In some embodiments, gate 306j and gate 308j are coupled together. In some embodiments, gate 306j and gate 308j are part of the same continuous structure.

In some embodiments, the set of gates 306 or 308 encapsulates the set of active regions 302 or 304.

Other configurations, arrangements on other layout levels or quantities of gates in the set of gates 306 and 308 are within the scope of the present disclosure.

Each contact of the set of contacts 310 or 312 corresponds to one or more drain or source terminals of transistors P1-L, P2-L, P3-L, P4-L, P1-R, P2-R, P3-R, P4-R, N1-L, N2-L, N3-L, N4-L, N1-R, N2-R, N3-R and N4-R of integrated circuits 100, 300, 400A, 400B, 500 or 600. In some embodiments, one or more contacts of the set of contacts 310 or 312 overlaps a pair of active regions of the set of active regions 302 and 304, thereby electrically coupling the pair of active regions of the set of active regions 302 and 304, and the source or drain of the corresponding transistors.

In some embodiments, the set of contacts 310 or 312 encapsulates the set of active regions 302 or 304.

In some embodiments, contact 310a corresponds to the drain terminal of NFET transistor N2-L, contact 310c corresponds to the drain terminals of NFET transistor N1-L and NFET transistor N1-R, contact 310e corresponds to the drain terminals of NFET transistor N2-R and NFET transistor N3-R, contact 310g corresponds to the drain terminals of NFET transistor N4-R and NFET transistor N4-L, and contact 310i corresponds to the drain terminal of NFET transistor N3-L.

In some embodiments, contact 310b corresponds to the source terminals of NFET transistor N2-L and NFET transistor N1-L, contact 310d corresponds to the source terminals of NFET transistor N1-R and NFET transistor N2-R, contact 310f corresponds to the source terminals of NFET transistor N3-R and NFET transistor N4-R, and contact 310h corresponds to the source terminals of NFET transistor N4-L and NFET transistor N3-L.

In some embodiments, contact 312a corresponds to the source terminal of PFET transistor P2-L.

In some embodiments, contact 312b corresponds to the drain terminal of PFET transistor P2-L and source terminal of PFET transistor P1-L.

In some embodiments, contact 312c corresponds to the drain terminal of PFET transistor P1-L and drain terminal of PFET transistor P1-R.

In some embodiments, contact 312d corresponds to the source terminal of PFET transistor P1-R and drain terminal of PFET transistor P2-R.

In some embodiments, contact 312e corresponds to the source terminal of PFET transistor P2-R and drain terminal of PFET transistor P3-R.

In some embodiments, contact 312f corresponds to the source terminal of PFET transistor P3-R and drain terminal of PFET transistor P4-R.

In some embodiments, contact 312g corresponds to the source terminal of PFET transistor P4-R and source terminal of PFET transistor P4-L.

In some embodiments, contact 312h corresponds to the drain terminal of PFET transistor P4-L and source terminal of PFET transistor P3-L.

In some embodiments, contact 312i corresponds to the drain terminal of PFET transistor P3-L.

In some embodiments, contact 314a corresponds to the drain terminals of NFET transistor N1-L and NFET transistor N1-R, the drain terminal of PFET transistor P1-L and the drain terminal of PFET transistor P1-R.

Other configurations, arrangements on other layout levels or quantities of contacts in the set of contacts 310, 312 and 314 are within the scope of the present disclosure.

The set of conductors 330 is M0 routing tracks. In some embodiments, the set of conductors 330 and 332 are routing tracks in other layers. In some embodiments, the set of conductors 330 corresponds to 2 M0 routing tracks.

The set of conductors 332 is BM0 routing tracks. In some embodiments, the set of conductors 332 corresponds to 2 BM0 routing tracks.

Other configurations, arrangements on other layout levels or quantities of conductors in the set of conductors 330 and 332 are within the scope of the present disclosure.

In some embodiments, power rail 336a of the set of power rails 336 is located on the front-side 303a of integrated circuit 100, 300, 400A, 400B, 500 or 600. In some embodiments, power rail 336a of the set of power rails 336 is configured to supply voltage VDD or reference supply voltage VSS.

In some embodiments, power rail 336b of the set of power rails 336 is located on the back-side 303b of integrated circuit 100, 300, 400A, 400B, 500 or 600. In some embodiments, power rail 336b of the set of power rails 336 is configured to supply reference supply voltage VSS or supply voltage VDD.

The set of vias 320 is configured to electrically couple a corresponding source or drain region of the set of active regions 302 to the set of conductors 330 by the set of contacts 310, and vice versa. The set of vias 320 is between the set of contacts 310 and the set of conductors 330.

The set of vias 322 is configured to electrically couple a corresponding source or drain region of the set of active regions 304 to the set of conductors 332 by the set of contacts 312, and vice versa. The set of vias 322 is between the set of contacts 312 and the set of conductors 332.

The set of vias 324 is configured to electrically couple one or more gates of the set of gates 306 to the set of conductors 330, and vice versa. The set of vias 324 is between the set of gates 306 and the set of conductors 330.

The set of vias 326 is configured to electrically couple one or more gates of the set of gates 308 to the set of conductors 332, and vice versa. The set of vias 326 is between the set of gates 308 and the set of conductors 332.

Via 320a electrically couples conductor 330e and contact 310a together. Via 320b electrically couples conductor 330e and at least one of contact 310c or 314a together. Via 320c electrically couples conductor 330e and contact 310e together. Via 320d electrically couples conductor 330e and contact 310g together. Via 320e electrically couples conductor 330e and contact 310i together.

Via 322a electrically couples conductor 332a and contact 312a together. Via 322b electrically couples conductor 332a and contact 312i together.

Via 324a electrically couples conductor 330a and gate 306b together. Via 324b electrically couples conductor 330b and gate 306c together. Via 324c electrically couples conductor 330b and gate 306d together. Via 324d electrically couples conductor 330c and gate 306g together. Via 324c electrically couples conductor 330c and gate 306h together. Via 324f electrically couples conductor 330d and gate 306i together.

Via 326a electrically couples conductor 332b and gate 308b together. Via 326b electrically couples conductor 332b and gate 308e together. Via 326c electrically couples conductor 332c and gate 308f together. Via 326d electrically couples conductor 332c and gate 308i together.

Other configurations, arrangements on other layout levels or quantities of vias in the set of vias 320, 322, 324 and 326 are within the scope of the present disclosure.

The set of conductors 350 corresponds to 5 M1 routing tracks. Other number of M1 routing tracks are within the scope of the present disclosure. In some embodiments, the set of conductors 350 are routing tracks in other metal layers.

In some embodiments, conductor 350a is an input pin configured to receive a signal A2, conductor 350b is an input pin configured to receive a signal A1, conductor 350d is an input pin configured to receive a signal A4, and conductor 350e is an input pin configured to receive a signal A3.

In some embodiments, conductor 350c is an output pin configured to output an output signal OUT on node ZN.

Other configurations, arrangements on other layout levels or quantities of conductors in the set of conductors 350 are within the scope of the present disclosure.

The set of vias 340 is configured to electrically couple the set of conductors 350 to the set of conductors 330, and vice versa. The set of vias 340 is between the set of set of conductors 350 and the set of conductors 330.

Via 340a electrically couples conductor 350a to conductor 330a.

Via 340b electrically couples conductor 350b to conductor 330b.

Via 340c electrically couples conductor 350c to conductor 330c.

Via 340d electrically couples conductor 350d to conductor 330c.

Via 340e electrically couples conductor 350c to conductor 330d.

In some embodiments, the set of gates 306 and 308 electrically couple the frontside 303a and the backside 303b of integrated circuit 300.

An input pin (e.g., conductor 350a) is electrically coupled to gate 306b, gate 308b, gate 308c and gate 306c. For example, conductor 350a is electrically coupled to conductor 330a by via 340a. Conductor 330a is electrically coupled to gate 306b by via 324a. Gate 306b is directly coupled to gate 308b, and therefore gate 306b is electrically coupled to gate 308b. Gate 308b is electrically coupled to conductor 332b by via 326a. Conductor 332b is electrically coupled to gate 308e by via 326b. Gate 308e is directly coupled to gate 306e, and therefore gate 308e is electrically coupled to gate 306c.

In some embodiments, by providing an electrical connection between an input pin (e.g., conductor 350a) and each of gate 306b, gate 308b, gate 308c and gate 306c, BM0 metallization levels can be utilized as additional routing resources thereby resulting in integrated circuit 300 having at least one of a reduced pitch, a smaller area or a smaller standard cell than other approaches.

An input pin (e.g., conductor 350c) is electrically coupled to gate 306i, gate 308i, gate 308f and gate 306f. For example, conductor 350e is electrically coupled to conductor 330d by via 340c. Conductor 330d is electrically coupled to gate 306i by via 324f. Gate 306i is directly coupled to gate 308i, and therefore gate 306i is electrically coupled to gate 308i. Gate 308i is electrically coupled to conductor 332c by via 326d. Conductor 332c is electrically coupled to gate 308f by via 326c. Gate 308f is directly coupled to gate 306f, and therefore gate 308f is electrically coupled to gate 306f.

In some embodiments, by providing an electrical connection between an input pin (e.g., conductor 350c) and each of gate 306i, gate 308i, gate 308f and gate 306f, BM0 metallization levels can be utilized as additional routing resources thereby resulting in integrated circuit 300 having at least one of a reduced pitch, a smaller area or a smaller standard cell than other approaches.

In some embodiments, the set of gates 306 and 308 electrically couple the frontside 303a and the backside 303b of integrated circuit 300, thereby utilizing BM0 metallization levels as additional routing resources resulting in integrated circuit 300 having at least one of a reduced pitch, a smaller area or a smaller standard cell than other approaches.

Other configurations, arrangements on other layout levels or quantities of vias in the set of vias 340 are within the scope of the present disclosure.

In some embodiments, at least one gate of the set of gates 306, 308, 506, 508, 606 or 608 are formed using a doped or non-doped polycrystalline silicon (or polysilicon). In some embodiments, at least one gate of the set of gates 306, 308, 506, 508, 606 or 608 includes a metal, such as Al, Cu, W, Ti, Ta, TiN, TaN, NiSi, CoSi, other suitable conductive materials, or combinations thereof.

In some embodiments, at least one contact of the set of contacts 310, 312, 314, 510, 512, 514, or at least one conductor of the set of conductors 330, 332, 350, 530, 532, 550, 552, 630, 632, 650, 652 or 670 or at least one via of the set of vias 320, 322, 324, 326, 340, 520, 524, 526, 540, 542, 624, 626, 640, 642 or 660 includes one or more layers of a conductive material, a metal, a metal compound or a doped semiconductor. In some embodiments, the conductive material includes Tungsten, Cobalt, Ruthenium, Copper, or the like or combinations thereof. In some embodiments, a metal includes at least Cu (Copper), Co, W, Ru, Al, or the like. In some embodiments, a metal compound includes at least AlCu, W-TiN, TiSix, NiSix, TiN, TaN, or the like. In some embodiments, a doped semiconductor includes at least doped silicon, or the like.

Other configurations or arrangements of integrated circuit 300 are within the scope of the present disclosure.

FIG. 4A is a block diagram of an integrated circuit 400A, in accordance with some embodiments.

Integrated circuit 400A comprises a flip-flop 402a and a flip-flop 402b.

In some embodiments, integrated circuit 400A is a flip-flop. In some embodiments, integrated circuit 400A is a multi-bit flip-flop (MBFF). In some embodiments, integrated circuit 400A is a two bit flip-flop. In other words, integrated circuit 400A includes two flip-flops (e.g., flip-flops 402a and 402b). Other numbers of bits or corresponding flip-flops in integrated circuit 400A are within the scope of the present disclosure. In some embodiments, integrated circuit 400A is a single bit flip-flop, and does not include flip-flop 402b.

In some embodiments, integrated circuit 400A is part of an integrated circuit (not shown) that includes other flip-flops, similar to flip-flop 400A, or one or more other flip-flops.

Integrated circuit 400A is configured to receive input signals IN1 and IN2.

Integrated circuit 400A is configured to generate output signals OUT1 and OUT2.

In some embodiments, one or more of flip-flops 402a or 402b are level triggered flip-flops. In some embodiments, one or more of flip-flops 402a or 402b are edge triggered flip-flops. In some embodiments, one or more of flip-flops 402a or 402b includes a DQ flip-flop, an SR-flip-flop, a T flip-flop, a JK flip-flop, or the like. Other types of flip-flops or configurations for at least flip-flop 402a or 402b are within the scope of the present disclosure.

In some embodiments, other numbers of inputs or outputs for integrated circuit 400A are within the scope of the present disclosure.

Other configurations or arrangements of integrated circuit 400A are within the scope of the present disclosure.

FIG. 4B is a circuit diagram of an integrated circuit 400B, in accordance with some embodiments.

In some embodiments, integrated circuit 400B is an embodiment of a portion of integrated circuit 400A.

Integrated circuit 400B includes PFET transistors P1, P2, P3, P4 and P5, and NFET transistors N1, N2, N3, N4, and N5.

A gate terminal of PFET transistor P1 is configured as an input node (not labelled) configured to receive an input signal IN1. A gate terminal of NFET transistor N1 is configured as an input node (not labelled) configured to receive input signal IN1.

In some embodiments, at least one of the gate terminal of PFET transistor P1 and the gate terminal of NFET transistor N1 is coupled together.

A gate terminal of PFET transistor P4 is configured as an input node (not labelled) configured to receive an input signal IN2. A gate terminal of NFET transistor N4 is configured as an input node (not labelled) configured to receive input signal IN2.

In some embodiments, at least one of the gate terminal of PFET transistor P4 and the gate terminal of NFET transistor N4 is coupled together.

At least a drain terminal of PFET transistor P1 and a drain terminal of NFET transistor N1 are coupled together, and are configured as an output node configured to output the output signal OUT1.

A source terminal of PFET transistor P1 and a source terminal of PFET transistor P2 are coupled together, and are further coupled to the voltage supply VDD. In some embodiments, a drain terminal of PFET transistor P2 and a drain terminal of PFET transistor P3 are coupled together.

A source terminal of NFET transistor N1 and a source terminal of NFET transistor N2 are coupled together, and are further coupled to the reference voltage supply VSS. In some embodiments, a drain terminal of NFET transistor N2 and a drain terminal of NFET transistor N3 are coupled together. In some embodiments, NFET transistor N1 and PFET transistor P1 are configured as an inverter. In some embodiments, NFET transistors N4 and N5 and PFET transistors P4 and P5 are configured as a stacked-gate.

Each of a gate terminal of PFET transistor P5, a gate terminal of NFET transistor N5, a gate terminal of PFET transistor P3 and a gate terminal of NFET transistor N3 is configured as an input node (not labelled) configured to receive the output signal OUT1. Each of the gate terminal of PFET transistor P5, the gate terminal of NFET transistor N5, the gate terminal of PFET transistor P3, the gate terminal of NFET transistor N3, the drain terminal of PFET transistor P1 and the drain terminal of NFET transistor N1 are coupled together.

At least a drain terminal of PFET transistor P5 and a drain terminal of NFET transistor N5 are coupled together, and are configured as an output node configured to output the output signal OUT2.

Each of a gate terminal of PFET transistor P2 and a gate terminal of NFET transistor N2 is configured as an input node (not labelled) configured to receive the output signal OUT2. Each of the gate terminal of PFET transistor P2, the gate terminal of NFET transistor N2, the drain terminal of PFET transistor P5 and the drain terminal of NFET transistor N5 are coupled together.

A source terminal of PFET transistor P5 and a drain terminal of PFET transistor P4 are coupled together. A source terminal of PFET transistor P4 and a source terminal of PFET transistor P3 are coupled together, and are further coupled to the voltage supply VDD.

A source terminal of NFET transistor N5 and a drain terminal of NFET transistor N4 are coupled together. A source terminal of NFET transistor N4 and a source terminal of NFET transistor N3 are coupled together, and are further coupled to the reference voltage supply VSS.

Other circuits, other types of transistors, and/or quantities of transistors are within the scope of various embodiments. For example, in some embodiments, integrated circuit 400B includes at least one of voltage supply node VDD or reference voltage supply node VSS, and at least one of the voltage supply node VDD or reference voltage supply node VSS replaces a connection between one or more drain/source terminals.

FIGS. 5A-5B are diagrams of an integrated circuit 500, in accordance with some embodiments.

FIGS. 5A-5B are corresponding diagrams of corresponding portions 500A-500B of an integrated circuit 500, simplified for case of illustration.

Portion 500A includes one or more features of integrated circuit 500 of the OD level, the POLY level, the MD level, the MDLI level, the M0 level, the M1 level, the VG level, the VD level and the V0 level.

Portion 500B includes one or more features of integrated circuit 500 of the OD level, the POLY level, the BMD level, the MDLI level, the BM0 level, the BVG level, the BVD level, the BM1 and the BV0 level.

Integrated circuit 500 is manufactured by a corresponding layout design similar to integrated circuit 500. Integrated circuit 500 is an embodiment of integrated circuit 400A or 400B, and similar detailed description is omitted. For brevity FIGS. 5A-5B are described as integrated circuit 500, but in some embodiments, FIGS. 5A-5B also correspond to layout designs similar to layout design 200, structural elements of integrated circuit 500 also correspond to layout patterns, and structural relationships including alignment, lengths and widths, as well as configurations and layers of a corresponding layout design of integrated circuit 500 are similar to the structural relationships and configurations and layers of integrated circuit 500, and similar detailed description will not be described for brevity.

In some embodiments, integrated circuit 500 is manufactured by a layout design similar to layout design 200, and similar detailed description is omitted for brevity.

Integrated circuit 500 includes at least the set of active regions 302 and 304, a set of gates 506, a set of gates 508, a set of contacts 510, a set of contacts 512, a set of contacts 514, a set of vias 520, a set of vias 524, a set of vias 526, a set of conductors 530, a set of conductors 532, the set of power rails 336, a set of vias 540, a set of conductors 550, a set of vias 542, a set of conductors 552, the substrate 390, and the insulating region 392.

Integrated circuit 500 is a variation of integrated circuit 300 (FIGS. 3A-3E). In comparison with integrated circuit 300 of FIGS. 3A-3E, the set of gates 506 of integrated circuit 500 replaces the set of gates 306, the set of gates 508 of integrated circuit 500 replaces the set of gates 308, the set of contacts 510 of integrated circuit 500 replaces the set of contacts 310, the set of contacts 512 of integrated circuit 500 replaces the set of contacts 312, the set of contacts 514 of integrated circuit 500 replaces the set of contacts 314, the set of vias 520 of integrated circuit 500 replaces the set of vias 320, the set of vias 524 of integrated circuit 500 replaces the set of vias 324, the set of vias 526 of integrated circuit 500 replaces the set of vias 326, the set of conductors 530 of integrated circuit 500 replaces the set of conductors 330, the set of conductors 532 of integrated circuit 500 replaces the set of conductors 332, the set of vias 540 of integrated circuit 500 replaces the set of vias 340, the set of conductors 550 of integrated circuit 500 replaces the set of conductors 350, and similar detailed description is therefore omitted.

In comparison with integrated circuit 300 of FIGS. 3A-3E, integrated circuit 500 further includes the set of vias 542 and the set of conductors 552.

Set of gates 506 includes at least gate 506a, 506b, . . . , 506f or 506g.

In comparison with integrated circuit 300 of FIGS. 3A-3E, at least one or more of gates 506a, 506b, . . . , 506f or 506g replaces at least one or more of gate 306a, 306b, . . . , 306i or 306j of the set of gates 306, and similar detailed description is therefore omitted.

The set of gates 506 and 508 correspond to one or more gates of transistors P1, P2, P3, P4, P5, N1, N2, N3, N4, and N5 of integrated circuit 400B or 500. In some embodiments, each of the gates in the set of gates 506 and 508 are shown in FIGS. 5A-5B with labels “P1, P2, P3, P4, P5, N1, N2, N3, N4, and N5” that identify corresponding transistors of FIG. 4B having corresponding gates in FIGS. 5A-5B, and are omitted for brevity.

In some embodiments, gate 506b is a gate of NFET transistor N1, gate 506c is a gate of NFET transistor N2, gate 506d is a gate of NFET transistor N3, gate 506e is a gate of NFET transistor N4, and gate 506f is a gate of NFET transistor N5.

In some embodiments, gate 506a is a dummy gate of a dummy transistor. In some embodiments, gate 506g is a dummy gate of a dummy transistor.

Set of gates 508 includes at least gate 508a, 508b, . . . , 508f or 508g.

In comparison with integrated circuit 300 of FIGS. 3A-3E, at least one or more of gates 508a, 508b, . . . , 508f or 508g replaces at least one or more of gate 308a, 308b, . . . , 308i or 308j of the set of gates 308, and similar detailed description is therefore omitted.

In some embodiments, gate 508b is a gate of PFET transistor P1, gate 508c is a gate of PFET transistor P2, gate 508d is a gate of PFET transistor P3, gate 508e is a gate of PFET transistor P4, and gate 508f is a gate of PFET transistor P5.

In some embodiments, gate 508a is a dummy gate of a dummy transistor. In some embodiments, gate 508g is a dummy gate of a dummy transistor.

Other configurations, arrangements on other layout levels or quantities of gates in the set of gates 506 and 508 are within the scope of the present disclosure.

Set of contacts 510 includes at least contact 510a, 510b, . . . , 510e or 510f.

In comparison with integrated circuit 300 of FIGS. 3A-3E, at least one or more of contact 510a, 510b, . . . , 510e or 510f replaces at least one or more of contact 310a, 310b, . . . , 310h or 310i of the set of contacts 310, and similar detailed description is therefore omitted.

Each contact of the set of contacts 510 or 512 corresponds to one or more drain or source terminals of transistors P1, P2, P3, P4, P5, N1, N2, N3, N4, and N5 of integrated circuits 400B or 500.

In some embodiments, contact 510a corresponds to the drain terminal of NFET transistor N1, contact 510b corresponds to the source terminal of NFET transistor N1 and the drain terminal of NFET transistor N2, contact 510c corresponds to the source terminal of NFET transistor N2 and the source terminal of NFET transistor N3, contact 510d corresponds to the drain terminal of NFET transistor N3 and the source terminal of NFET transistor N4, contact 510e corresponds to the drain terminal of NFET transistor N4 and the source terminal of NFET transistor N5, and contact 510f corresponds to the drain terminal of NFET transistor N5.

Set of contacts 512 includes at least contact 512a, 512b, . . . , 512e or 512f.

In comparison with integrated circuit 300 of FIGS. 3A-3E, at least one or more of contact 512a, 512b, . . . , 512e or 512f replaces at least one or more of contact 312a, 312b, . . . , 312h or 312i of the set of contacts 312, and similar detailed description is therefore omitted.

In some embodiments, contact 512a corresponds to the drain terminal of PFET transistor P1, contact 512b corresponds to the source terminal of PFET transistor P1 and the drain terminal of PFET transistor P2, contact 512c corresponds to the source terminal of PFET transistor P2 and the source terminal of PFET transistor P3, contact 512d corresponds to the drain terminal of PFET transistor P3 and the source terminal of PFET transistor P4, contact 512e corresponds to the drain terminal of PFET transistor P4 and the source terminal of PFET transistor P5, and contact 512f corresponds to the drain terminal of PFET transistor P5.

Set of contacts 514 includes at least contact 514a or 514b.

In comparison with integrated circuit 300 of FIGS. 3A-3E, at least one or more of contact 514a or 514b replaces at least one or more of contact 314a of the set of contacts 314, and similar detailed description is therefore omitted.

In some embodiments, contact 514a corresponds to the drain terminal of NFET transistor N1 and the drain terminal of PFET transistor P1.

In some embodiments, contact 514b corresponds to the drain terminal of NFET transistor N5 and the drain terminal of PFET transistor P5.

Other configurations, arrangements on other layout levels or quantities of contacts in the set of contacts 510, 512 and 514 are within the scope of the present disclosure.

Set of conductors 530 includes at least conductor 530a, 530b or 530c.

In comparison with integrated circuit 300 of FIGS. 3A-3E, at least one or more of conductor 530a, 530b or 530c replaces at least one or more of conductor 330a, 330b, 330c, 330d or 330e of the set of conductors 330, and similar detailed description is therefore omitted.

Set of conductors 532 includes at least conductor 532a or 532b.

In comparison with integrated circuit 300 of FIGS. 3A-3E, at least one or more of conductor 532a, 532b replaces at least one or more of conductor 332a, 332b or 332c of the set of conductors 332, and similar detailed description is therefore omitted.

The set of conductors 530 is M0 routing tracks. In some embodiments, the set of conductors 530 and 532 are routing tracks in other layers. In some embodiments, the set of conductors 530 corresponds to 2 M0 routing tracks.

The set of conductors 532 is BM0 routing tracks. In some embodiments, the set of conductors 532 corresponds to 2 BM0 routing tracks.

Other configurations, arrangements on other layout levels or quantities of conductors in the set of conductors 530 and 532 are within the scope of the present disclosure.

Set of vias 520 includes at least via 520a or 520b.

In comparison with integrated circuit 300 of FIGS. 3A-3E, at least one or more of via 520a, or 520b replaces at least one or more of via 320a, 320b, . . . , 320e of the set of vias 320, and similar detailed description is therefore omitted.

Set of vias 524 includes at least via 524a, 524b or 524c.

In comparison with integrated circuit 300 of FIGS. 3A-3E, at least one or more of via 524a, 524b or 524c replaces at least one or more of via 324a, 324b, . . . , 324f of the set of vias 324, and similar detailed description is therefore omitted.

Set of vias 526 includes at least via 526a, 526b or 526c.

In comparison with integrated circuit 300 of FIGS. 3A-3E, at least one or more of via 526a, 526b or 526c replaces at least one or more of via 326a, 326b, . . . , 326d of the set of vias 326, and similar detailed description is therefore omitted.

Via 520a electrically couples conductor 530b and at least one of contact 510a or 514a together.

Via 520b electrically couples conductor 530a and contact 510f together.

Via 524a electrically couples conductor 530a and gate 506c together.

Via 524b electrically couples conductor 530b and gate 506d together.

Via 524c electrically couples conductor 530c and gate 506e together.

Via 526a electrically couples conductor 532a and gate 508b together.

Via 526b electrically couples conductor 532b and gate 508d together.

Via 526c electrically couples conductor 532b and gate 508f together.

Other configurations, arrangements on other layout levels or quantities of vias in the set of vias 520, 524 and 526 are within the scope of the present disclosure.

Set of conductors 550 includes at least conductor 550a.

In comparison with integrated circuit 300 of FIGS. 3A-3E, at least one or more of conductor 550a replaces at least one or more of conductor 350a, 350b, 350c, 350d or 350e of the set of conductors 350, and similar detailed description is therefore omitted.

The set of conductors 550 corresponds to M1 routing tracks. Other number of M1 routing tracks are within the scope of the present disclosure. In some embodiments, the set of conductors 550 are routing tracks in other metal layers.

In some embodiments, conductor 550a is an input pin configured to receive a signal IN2.

Set of conductors 552 includes at least conductor 552a extending in the second direction Y.

In comparison with integrated circuit 300 of FIGS. 3A-3E, at least one or more of conductor 552a is similar to at least one or more of conductor 350a, 350b, 350c, 350d or 350e of the set of conductors 350, and similar detailed description is therefore omitted.

The set of conductors 552 corresponds to BM1 routing tracks. Other number of BM1 routing tracks are within the scope of the present disclosure. In some embodiments, the set of conductors 552 are routing tracks in other metal layers.

In some embodiments, conductor 552a is an input pin configured to receive a signal IN1. In some embodiments, the set of conductors 552 is located on the ninth layout level.

Other configurations, arrangements on other layout levels or quantities of conductors in the set of conductors 550 or 552 are within the scope of the present disclosure.

Set of vias 540 includes at least via 540a.

In comparison with integrated circuit 300 of FIGS. 3A-3E, at least one or more of via 540a replaces at least one or more of via 340a, 340b, . . . , 340e of the set of vias 340, and similar detailed description is therefore omitted.

Via 540a electrically couples conductor 550a and conductor 530c together.

Set of vias 542 includes at least via 542a.

In comparison with integrated circuit 300 of FIGS. 3A-3E, at least one or more of via 542a is similar to at least one or more of via 340a, 340b, . . . , 340e of the set of vias 340, and similar detailed description is therefore omitted.

Via 542a electrically couples conductor 552a and conductor 532a together.

Other configurations, arrangements on other layout levels or quantities of vias in the set of vias 540 and 542 are within the scope of the present disclosure.

In some embodiments, the set of gates 506 and 508 electrically couple the frontside 303a and the backside 303b of integrated circuit 500.

An output node (e.g., conductor 532b) is electrically coupled to gate 506d, gate 508d, gate 508f and gate 506f. In some embodiments, the drain terminal of NFET transistor N1 and the drain terminal of PFET transistor P1 are electrically coupled to gate 506d of NFET transistor N3, gate 508d of PFET transistor P3, gate 508f of PFET transistor P5 and gate 506f of NFET transistor N5. For example, contact 512a is electrically coupled to contact 510a by contact 514a. Contact 510a is electrically coupled to conductor 530b by via 520a. Conductor 530b is electrically coupled to gate 506d by via 524b. Gate 506d is directly coupled to gate 508d, and therefore gate 506d is electrically coupled to gate 508d. Gate 508d is electrically coupled to conductor 532b by via 526b. Conductor 532b is electrically coupled to gate 508f by via 526c. Gate 508f is directly coupled to gate 506f, and therefore gate 508f is electrically coupled to gate 506f.

In some embodiments, by providing an electrical connection between an output node (e.g., conductor 532b) and each of gate 506d, gate 508d, gate 508f and gate 506f, BM0 metallization levels can be utilized as additional routing resources thereby resulting in integrated circuit 500 having at least one of a reduced pitch, a smaller area or a smaller standard cell than other approaches.

In some embodiments, the set of gates 506 and 508 electrically couple the frontside 303a and the backside 303b of integrated circuit 500.

An output node (e.g., conductor 530a) is electrically coupled to gate 506c and gate 506d. In some embodiments, the drain terminal of NFET transistor N5 and the drain terminal of PFET transistor P5 are electrically coupled to gate 506c of NFET transistor N2 and gate 508c of PFET transistor P2. For example, contact 512f is electrically coupled to contact 510f by contact 514b. Contact 510f is electrically coupled to conductor 530a by via 520b. Conductor 530a is electrically coupled to gate 506c by via 524a. Gate 506c is directly coupled to gate 508c, and therefore gate 506c is electrically coupled to gate 508c.

In some embodiments, the set of gates 506 and 508 electrically couple the frontside 303a and the backside 303b of integrated circuit 500, thereby utilizing BM0 metallization levels as additional routing resources resulting in integrated circuit 500 having at least one of a reduced pitch, a smaller area or a smaller standard cell than other approaches.

In some embodiments, by providing an electrical connection between the drain terminal of NFET transistor N5 and the drain terminal of PFET transistor P5 to each of gate 506c and gate 508c by an output node (e.g., conductor 530a), BM0 metallization levels can be utilized as additional routing resources thereby resulting in integrated circuit 500 having at least one of a reduced pitch, a smaller area or a smaller standard cell than other approaches.

In some embodiments, the set of gates 506 and 508 electrically couple the frontside 303a and the backside 303b of integrated circuit 500, thereby resulting in no vias in the set of vias 526 on the backside 303b that are positioned directly over the active regions 302 or 304 thus reducing mask costs, thereby resulting in integrated circuit 500 with a lower process cost compared to other approaches.

In some embodiments, the set of gates 506 and 508 electrically couple the frontside 303a and the backside 303b of integrated circuit 500, thereby resulting in V0 vias in the set of vias 540 that are positioned in adjacent M0 tracks thus reducing mask costs, thereby resulting in integrated circuit 500 with a lower process cost compared to other approaches.

Other configurations or arrangements of integrated circuit 500 are within the scope of the present disclosure.

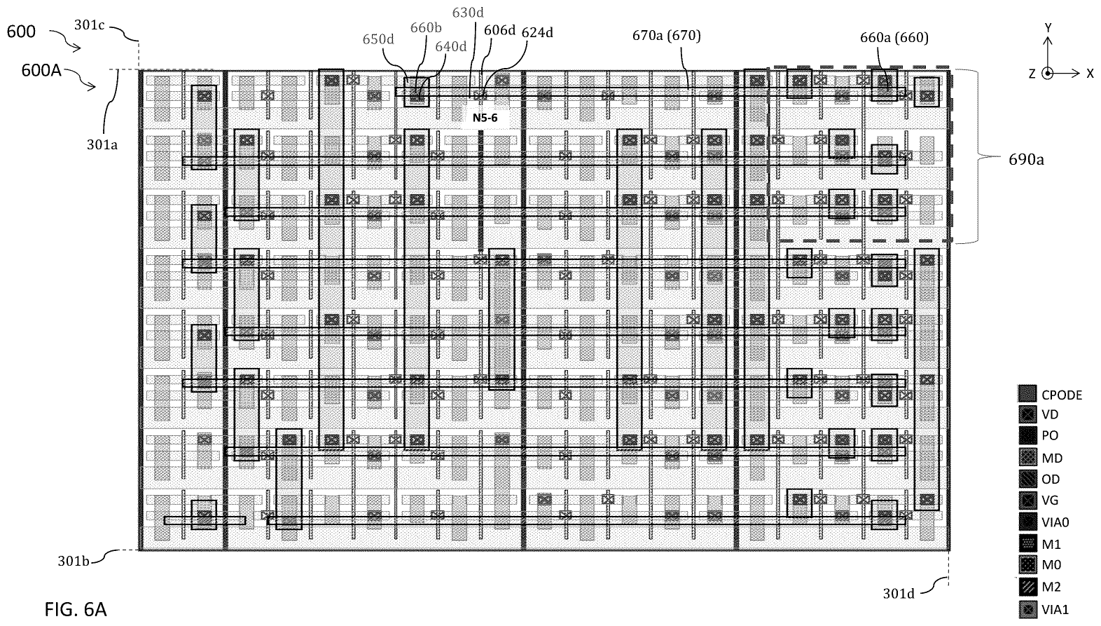

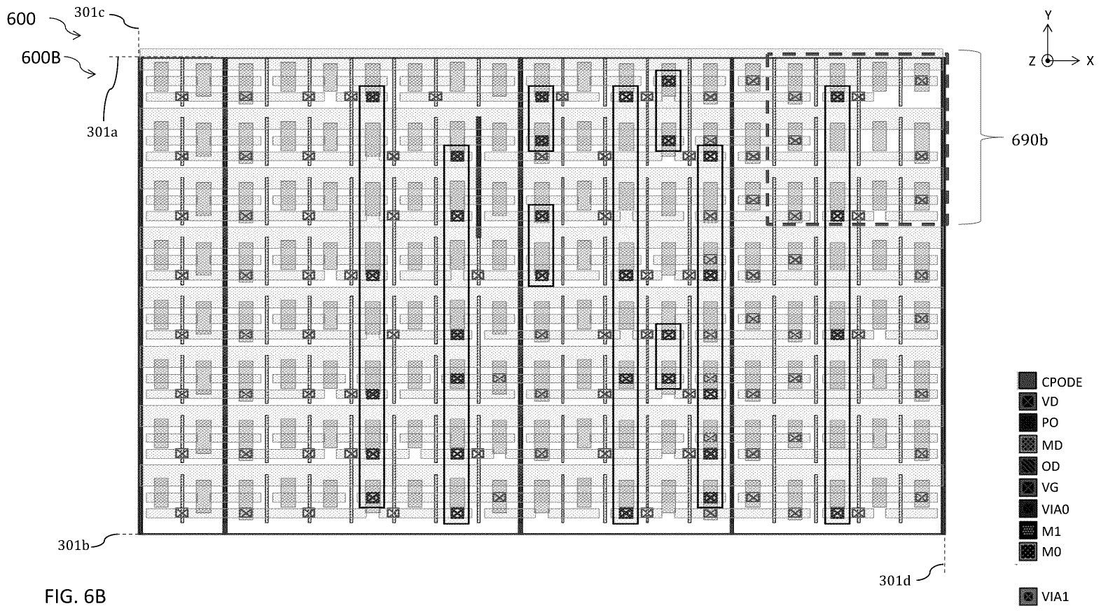

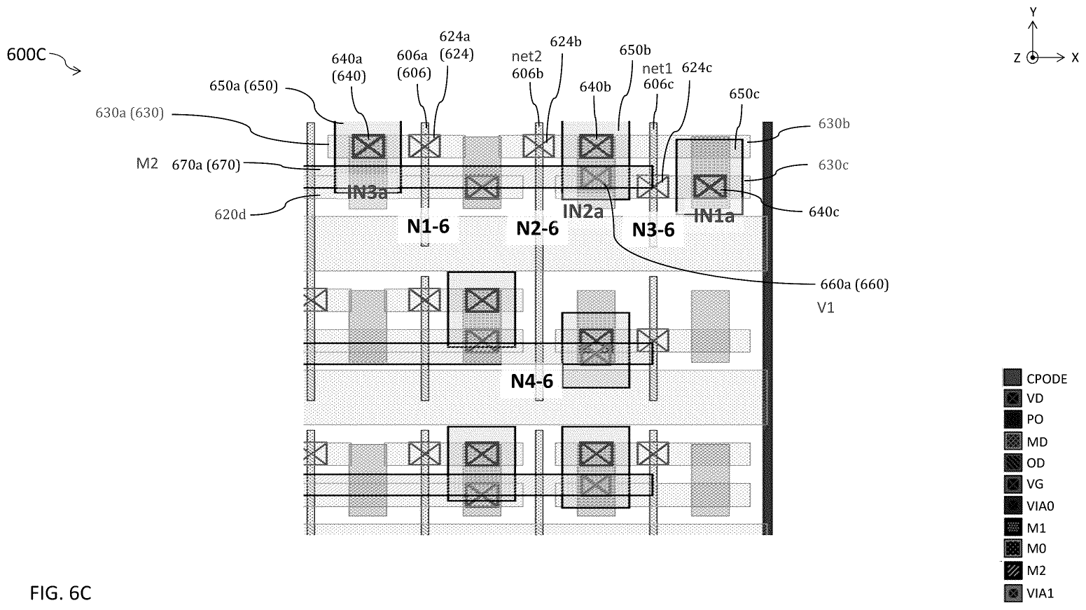

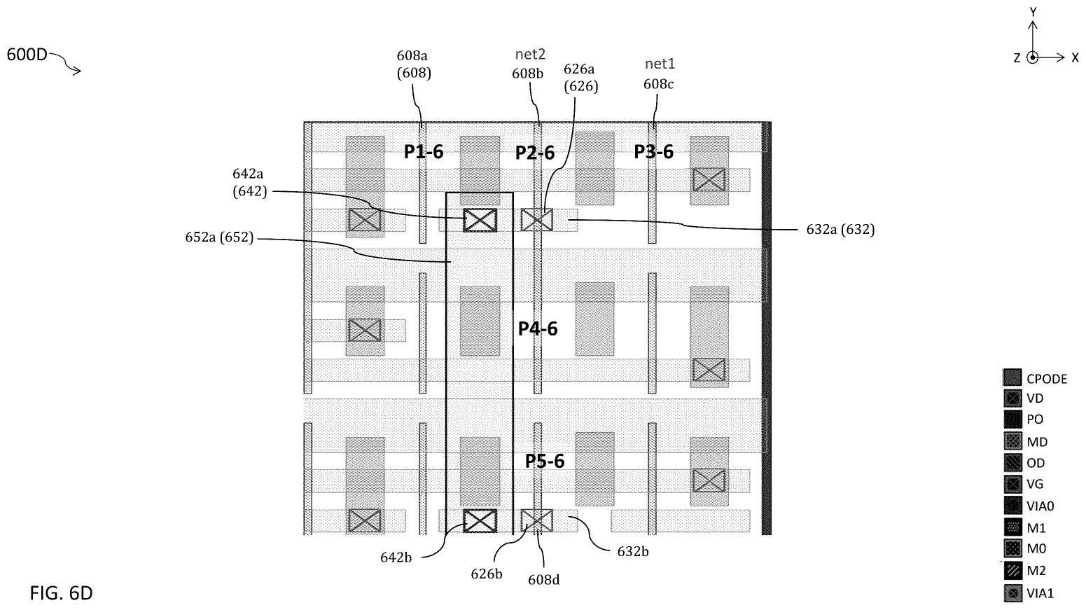

FIGS. 6A-6D are diagrams of an integrated circuit 600, in accordance with some embodiments.

FIGS. 6A-6B are corresponding diagrams of corresponding portions 600A-600B of an integrated circuit 600, simplified for case of illustration.

FIGS. 6C-6D are corresponding diagrams of corresponding portions 690a-690b of an integrated circuit 600, simplified for case of illustration.

Portion 600A includes one or more features of integrated circuit 600 of the POLY level, the MD level, the MDLI level, the M0 level, the M1 level, the VG level, the VD level and the V0 level, a metal 2 (M2) and a via over metal 1 (V1) level.

Portion 600B includes one or more features of integrated circuit 600 of the POLY level, the BMD level, the MDLI level, the BM0 level, the BVG level, the BVD level, the BM1 and the BV0 level.

Portion 690a includes a zoomed in portion of portion 600A of FIG. 6A, and similar detailed description will not be described for brevity.

Portion 690b includes a zoomed in portion of portion 600B of FIG. 6B, and similar detailed description will not be described for brevity.

Integrated circuit 600 is manufactured by a corresponding layout design similar to integrated circuit 600. Integrated circuit 600 is an embodiment of integrated circuit 400A or 400B, and similar detailed description is omitted. For brevity FIGS. 6A-6D are described as integrated circuit 600, but in some embodiments, FIGS. 6A-6D also correspond to layout designs similar to layout design 200, structural elements of integrated circuit 600 also correspond to layout patterns, and structural relationships including alignment, lengths and widths, as well as configurations and layers of a corresponding layout design of integrated circuit 600 are similar to the structural relationships and configurations and layers of integrated circuit 600, and similar detailed description will not be described for brevity.

In some embodiments, integrated circuit 600 is manufactured by a layout design similar to layout design 200, and similar detailed description is omitted for brevity.

In some embodiments, at least a signal IN2a or IN1a corresponds to signal IN1 in FIG. 4A, and similar detailed description is omitted for brevity. In some embodiments, a signal IN3a corresponds to signal IN2 in FIG. 4A, and similar detailed description is omitted for brevity.

Integrated circuit 600 includes at least a set of gates 606, a set of gates 608, a set of vias 624, a set of vias 626, a set of conductors 630, a set of conductors 632, a set of vias 640, a set of conductors 650, a set of vias 642, a set of conductors 652, a set of vias 660, a set of conductors 670, the substrate 390, and the insulating region 392.

Integrated circuit 600 is a variation of integrated circuit 300 (FIGS. 3A-3E) or 500 (FIGS. 5A-5B). In comparison with integrated circuit 300 of FIGS. 3A-3E or integrated circuit 500 of FIGS. 5A-5B, the set of gates 606 of integrated circuit 600 replaces the set of gates 306, the set of gates 608 of integrated circuit 600 replaces the set of gates 308, the set of vias 624 of integrated circuit 600 replaces the set of vias 324, the set of vias 626 of integrated circuit 600 replaces the set of vias 326, the set of conductors 630 of integrated circuit 600 replaces the set of conductors 330, the set of conductors 632 of integrated circuit 600 replaces the set of conductors 332, the set of vias 640 of integrated circuit 600 replaces the set of vias 340, the set of conductors 650 of integrated circuit 600 replaces the set of conductors 350, and similar detailed description is therefore omitted.

In comparison with integrated circuit 500 of FIGS. 5A-5B, integrated circuit 600 further includes the set of vias 660 and the set of conductors 670.

Set of gates 606 includes at least gate 606a, 606b, 606c or 606d.

In comparison with integrated circuit 300 of FIGS. 3A-3E, at least one or more of gates 606a, 606b, 606c or 606d replaces at least one or more of gate 306a, 306b, . . . , 306i or 306j of the set of gates 306, and similar detailed description is therefore omitted.

The set of gates 606 and 608 correspond to one or more gates of transistors P1-6, P2-6, P3-6, P4-6, P5-6, N1-6, N2-6, N3-6 and N4-6 of integrated circuit 600. In some embodiments, each of the gates in the set of gates 606 and 608 are shown in FIGS. 6A-6D with labels “P1-6, P2-6, P3-6, P4-6, P5-6, N1-6, N2-6, N3-6 and N4-6” that identify corresponding transistors of FIG. 4A having corresponding gates in FIGS. 6A-6D, and are omitted for brevity.

In some embodiments, gate 606a is a gate of NFET transistor N1-6, gate 606b is a gate of NFET transistor N2-6 and a gate of NFET transistor N4-6, and gate 606c is a gate of NFET transistor N3-6.

Set of gates 608 includes at least gate 608a, 608b, 608c or 608d.

In comparison with integrated circuit 300 of FIGS. 3A-3E, at least one or more of gates 608a, 608b, 608c or 608d replaces at least one or more of gate 308a, 308b, . . . , 308i or 308j of the set of gates 308, and similar detailed description is therefore omitted.

In some embodiments, gate 608a is a gate of PFET transistor P1-6, gate 608b is a gate of PFET transistor P2-6 and a gate of PFET transistor P4-6, gate 608c is a gate of PFET transistor P3-6, and gate 608d is a gate of PFET transistor P5-6.

Other configurations, arrangements on other layout levels or quantities of gates in the set of gates 606 and 608 are within the scope of the present disclosure.

Set of conductors 630 includes at least conductor 630a, 630b, 630c or 630d.

In comparison with integrated circuit 300 of FIGS. 3A-3E, at least one or more of conductor 630a, 630b, 630c or 630d replaces at least one or more of conductor 330a, 330b, 330c, 330d or 330e of the set of conductors 330, and similar detailed description is therefore omitted.

Set of conductors 632 includes at least conductor 632a or 632b.

In comparison with integrated circuit 300 of FIGS. 3A-3E, at least one or more of conductor 632a or 632b replaces at least one or more of conductor 332a, 332b or 332c of the set of conductors 332, and similar detailed description is therefore omitted.

The set of conductors 630 is M0 routing tracks. In some embodiments, the set of conductors 630 and 632 are routing tracks in other layers. In some embodiments, the set of conductors 630 corresponds to 2 M0 routing tracks.

The set of conductors 632 is BM0 routing tracks. In some embodiments, the set of conductors 632 corresponds to 2 BM0 routing tracks.

Other configurations, arrangements on other layout levels or quantities of conductors in the set of conductors 630 and 632 are within the scope of the present disclosure.

Set of vias 624 includes at least via 624a, 624b or 624c.

In comparison with integrated circuit 300 of FIGS. 3A-3E, at least one or more of via 624a, 624b or 624c replaces at least one or more of via 324a, 324b, . . . , 324f of the set of vias 324, and similar detailed description is therefore omitted.

Set of vias 626 includes at least via 626a or 626b.

In comparison with integrated circuit 300 of FIGS. 3A-3E, at least one or more of via 626a, or 626b replaces at least one or more of via 326a, 326b, . . . , 326d of the set of vias 326, and similar detailed description is therefore omitted.

Via 624a electrically couples conductor 630a and gate 606a together.

Via 624b electrically couples conductor 630b and gate 606b together.

Via 624c electrically couples conductor 630c and gate 606c together.

Via 626a electrically couples conductor 632a and gate 608b together.

Via 626b electrically couples conductor 632b and gate 608d together.

Other configurations, arrangements on other layout levels or quantities of vias in the set of vias 624 and 626 are within the scope of the present disclosure.

Set of conductors 650 includes at least conductor 650a, 650b, 650c or 650d.

In comparison with integrated circuit 300 of FIGS. 3A-3E, at least one or more of conductor 650a, 650b, 650c or 650d replaces at least one or more of conductor 350a, 350b, 350c, 350d or 350c of the set of conductors 350, and similar detailed description is therefore omitted.

The set of conductors 650 corresponds to M1 routing tracks. Other number of M1 routing tracks are within the scope of the present disclosure. In some embodiments, the set of conductors 650 are routing tracks in other metal layers.

In some embodiments, conductor 650a is an input pin configured to receive a signal IN3a.

In some embodiments, conductor 650b is an input pin configured to receive a signal IN2a.

In some embodiments, conductor 650c is an input pin configured to receive a signal IN1a.

In some embodiments, conductor 650d is an input pin configured to receive signal IN2a. Set of conductors 652 includes at least conductor 652a.

In comparison with integrated circuit 500 of FIGS. 5A-5B, at least one or more of conductor 652a replaces at least one or more of conductor 552a of the set of conductors 552, and similar detailed description is therefore omitted.

The set of conductors 652 corresponds to BM1 routing tracks. Other number of BM1 routing tracks are within the scope of the present disclosure. In some embodiments, the set of conductors 652 are routing tracks in other metal layers.

In some embodiments, conductor 652a is a node configured to electrically couple gate 608b and gate 608d together.

Other configurations, arrangements on other layout levels or quantities of conductors in the set of conductors 650 or 652 are within the scope of the present disclosure.

Set of vias 640 includes at least via 640a, 640b, 640c or 640d.

In comparison with integrated circuit 300 of FIGS. 3A-3E, at least one or more of via 640a, 640b, 640c or 640d replaces at least one or more of via 340a, 340b, . . . , 340e of the set of vias 340, and similar detailed description is therefore omitted.

Via 640a electrically couples conductor 650a and conductor 630a together.

Via 640b electrically couples conductor 650b and conductor 630b together.

Via 640c electrically couples conductor 650c and conductor 630c together.

Via 640d electrically couples conductor 650d and conductor 630d together.

Set of vias 642 includes at least via 642a or 642b.

In comparison with integrated circuit 300 of FIGS. 3A-3E, at least one or more of via 642a or 642b is similar to at least one or more of via 340a, 340b, . . . , 340e of the set of vias 340, and similar detailed description is therefore omitted.

Via 642a electrically couples conductor 652a and conductor 632a together.

Via 642b electrically couples conductor 652a and conductor 632b together.

Other configurations, arrangements on other layout levels or quantities of vias in the set of vias 640 and 642 are within the scope of the present disclosure.

Set of conductors 670 includes at least conductor 670a extending in the first direction X.

In comparison with integrated circuit 300 of FIGS. 3A-3E, at least one or more of conductor 670a is similar to at least one or more of conductor 350a, 350b, 350c, 350d or 350e of the set of conductors 350, and similar detailed description is therefore omitted.

Each conductor in the set of conductors 670 is separated from another conductor in the set of conductors 670 in the second direction Y.

The set of conductors 670 overlap at least one of the set of active regions 302 or 304, the set of gates 306 or 308 or the set of conductors 630, 632, 650 or 652.

The set of conductors 670 corresponds to M2 routing tracks. Other number of M2 routing tracks are within the scope of the present disclosure. In some embodiments, the set of conductors 670 are routing tracks in other metal layers.

In some embodiments, the set of conductors 670 is located on a tenth layout level.

In some embodiments, the tenth layout level is different from at least one of the first layout level, the second layout level, the third layout level, the fourth layout level, the fifth layout level, the sixth layout level, the seventh layout level, the eighth layout level or the ninth layout level. In some embodiments, the tenth layout level corresponds to the M2 level of one or more of layout design 200 or integrated circuits 100, 300, 400A, 400B, 500 or 600. In some embodiments, the M2 level is above the OD level, the POLY level, the MD level, the M0 level, the M1 level, the BMD level, the BM0 level and the BM1 level.

Other configurations, arrangements on other layout levels or quantities of conductors in the set of conductors 670 are within the scope of the present disclosure.

Set of vias 660 includes at least via 660a or 660b.

The set of vias 660 is positioned at a via over M1 (V1) level of integrated circuit 600.

In comparison with integrated circuit 300 of FIGS. 3A-3E, at least one or more of via 660a, or 660b is similar to at least one or more of via 340a, 340b, . . . , 340e of the set of vias 340, and similar detailed description is therefore omitted.

Via 660a electrically couples conductor 670a and conductor 650b together.

Via 660b electrically couples conductor 670a and conductor 650d together.

Other configurations, arrangements on other layout levels or quantities of vias in the set of vias 660 are within the scope of the present disclosure.

In some embodiments, the set of gates 606 and 608 electrically couple the frontside 303a and the backside 303b of integrated circuit 600.

An input pin (e.g., conductor 670a) is electrically coupled to gate 606b, gate 608b, gate 608d and gate 606d. In some embodiments, each of the gate 606b of NFET transistor N2-6 and NFET transistor N4-6, the gate 608b of PFET transistor P2-6, gate 606d of NFET transistor N5-6, and gate 608d of PFET transistor P5-6 are electrically coupled together.

For example, conductor 670a is electrically coupled to conductor 650b by via 660a. Conductor 650b is electrically coupled to conductor 630b by via 640b. Conductor 630b is electrically coupled to gate 606b by via 624b. Gate 606b is directly coupled to gate 608b, and therefore gate 606b is electrically coupled to gate 608b. Gate 608b is electrically coupled to conductor 632a by via 626a. Conductor 632a is electrically coupled to conductor 652a by via 642a. Conductor 652a is electrically coupled to conductor 632b by via 642b. Conductor 632b is electrically coupled to gate 608d by via 626b.

Conductor 670a is further electrically coupled to conductor 650d by via 660b. Conductor 650d is electrically coupled to conductor 630d by via 640d. Conductor 630d is electrically coupled to gate 606d by via 624d.

In some embodiments, the set of gates 606 and 608 electrically couple the frontside 303a and the backside 303b of integrated circuit 600, thereby utilizing BM0 metallization levels as additional routing resources resulting in integrated circuit 600 having at least one of a reduced pitch, a smaller area or a smaller standard cell than other approaches.

In some embodiments, the set of gates 606 and 608 electrically couple the frontside 303a and the backside 303b of integrated circuit 600, thereby resulting in less M2 cut processes to cut the set of conductors 670 along the cell boundaries 301c or 301d thereby resulting in integrated circuit 600 with a lower process cost compared to other approaches.

In some embodiments, by providing an electrical connection between an input pin (e.g., conductor 670a) and each of gate 606b, gate 608b, gate 608d and gate 606d, BM0 metallization levels can be utilized as additional routing resources thereby resulting in integrated circuit 600 having at least one of a reduced pitch, a smaller area or a smaller standard cell than other approaches.

In some embodiments, integrated circuit 600 achieves one or more of the benefits described herein.

Other configurations or arrangements of integrated circuit 600 are within the scope of the present disclosure.

FIG. 7A-7B are functional flow charts of corresponding methods 700A-700B of manufacturing an IC device, in accordance with some embodiments. It is understood that additional operations may be performed before, during, and/or after the method 700A-700B depicted in FIG. 7A-7B, and that some other processes may only be briefly described herein.

In some embodiments, other order of operations of method 700A-900 is within the scope of the present disclosure. Method 700A-900 includes exemplary operations, but the operations are not necessarily performed in the order shown. Operations may be added, replaced, changed order, and/or eliminated as appropriate, in accordance with the spirit and scope of disclosed embodiments. In some embodiments, one or more of the operations of at least method 700A, 700B, 800 or 900 is not performed.

In some embodiments, method 700A-700B is an embodiment of operation 804 of method 800. In some embodiments, the methods 700A-900 are usable to manufacture or fabricate at least integrated circuit 100, 300, 400A, 400B, 500 or 600, or an integrated circuit with similar features as at least layout design 200.

In operation 702 of method 700A, a first set of transistors and a second set of transistors are fabricated on a front-side 303a of a semiconductor wafer or substrate. In some embodiments, the first set of transistors or the second set of transistors of method 700A-700B includes one or more transistors in at least the set of active regions 302 or 304. In some embodiments, the first set of transistors or the second set of transistors of method 700A-700B includes one or more transistors described herein.

In some embodiments, operation 702 includes fabricating source and drain regions of the set of transistors in a first well. In some embodiments, the first well comprises p-type dopants. In some embodiments, the p-type dopants include boron, aluminum or other suitable p-type dopants. In some embodiments, the first well comprises an cpi-layer grown over a substrate. In some embodiments, the epi-layer is doped by adding dopants during the epitaxial process. In some embodiments, the epi-layer is doped by ion implantation after the epi-layer is formed. In some embodiments, the first well is formed by doping the substrate. In some embodiments, the doping is performed by ion implantation. In some embodiments, the first well has a dopant concentration ranging from 1×10¹² atoms/cm³ to 1×10¹⁴ atoms/cm³.

In some embodiments, the first well comprises n-type dopants. In some embodiments, the n-type dopants include phosphorus, arsenic or other suitable n-type dopants. In some embodiments, the n-type dopant concentration ranges from about 1×10¹² atoms/cm³ to about 1×10¹⁴ atoms/cm³.

In some embodiments, the formation of the source/drain features includes, a portion of the substrate is removed to form recesses at an edge of spacers, and a filling process is then performed by filling the recesses in the substrate. In some embodiments, the recesses are etched, for example, a wet etching or a dry etching, after removal of a pad oxide layer or a sacrificial oxide layer. In some embodiments, the etch process is performed to remove a top surface portion of the active region adjacent to an isolation region, such as an STI region. In some embodiments, the filling process is performed by an epitaxy or epitaxial (cpi) process. In some embodiments, the recesses are filled using a growth process which is concurrent with an etch process where a growth rate of the growth process is greater than an etch rate of the etch process. In some embodiments, the recesses are filled using a combination of growth process and etch process. For example, a layer of material is grown in the recess and then the grown material is subjected to an etch process to remove a portion of the material. Then a subsequent growth process is performed on the etched material until a desired thickness of the material in the recess is achieved. In some embodiments, the growth process continues until a top surface of the material is above the top surface of the substrate. In some embodiments, the growth process is continued until the top surface of the material is co-planar with the top surface of the substrate. In some embodiments, a portion of the first well is removed by an isotropic or an anisotropic etch process. The etch process selectively etches the first well without etching a gate structure and any spacers. In some embodiments, the etch process is performed using a reactive ion etch (RIE), wet etching, or other suitable techniques. In some embodiments, a semiconductor material is deposited in the recesses to form the source/drain features. In some embodiments, an epi process is performed to deposit the semiconductor material in the recesses. In some embodiments, the epi process includes a selective epitaxy growth (SEG) process, CVD process, molecular beam epitaxy (MBE), other suitable processes, and/or combination thereof. The epi process uses gaseous and/or liquid precursors, which interact with a composition of substrate. In some embodiments, the source/drain features include epitaxially grown silicon (cpi Si), silicon carbide, or silicon germanium. Source/drain features of the IC device associated with the gate structure are in-situ doped or undoped during the epi process in some instances. When source/drain features are undoped during the epi process, source/drain features are doped during a subsequent process in some instances. The subsequent doping process is achieved by an ion implantation, plasma immersion ion implantation, gas and/or solid source diffusion, other suitable processes, and/or combination thereof. In some embodiments, source/drain features are further exposed to annealing processes after forming source/drain features and/or after the subsequent doping process.

In some embodiments, operation 702 further includes operation 702a. In some embodiments, operation 702a includes forming a first gate region of the first set of transistors. In some embodiments, the first gate region of the first set of transistors of method 700A-700B includes the set of gates 306, 308, 506, 508, 606 or 608.

In some embodiments, operation 702 further includes operation 702b. In some embodiments, operation 702b includes forming a second gate region of the second set of transistors. In some embodiments, the second gate regions of the second set of transistors of method 700A-700B include the set of gates 306, 308, 506, 508, 606 or 608.

In some embodiments, the first and second gate region is between the drain region and the source region. In some embodiments, the first and second gate region is over the first well and the substrate. In some embodiments, fabricating the first and second gate regions of operations 702a and 702b include performing one or more deposition processes to form one or more dielectric material layers. In some embodiments, a deposition process includes a chemical vapor deposition (CVD), a plasma enhanced CVD (PECVD), an atomic layer deposition (ALD), or other process suitable for depositing one or more material layers. In some embodiments, fabricating the first and second gate regions includes performing one or more deposition processes to form one or more conductive material layers. In some embodiments, fabricating the first and second gate regions includes forming gate electrodes or dummy gate electrodes. In some embodiments, fabricating the gate regions includes depositing or growing at least one dielectric layer, e.g., gate dielectric. In some embodiments, gate regions are formed using a doped or non-doped polycrystalline silicon (or polysilicon). In some embodiments, the first and second gate regions include a metal, such as Al, Cu, W, Ti, Ta, TiN, TaN, NiSi, CoSi, other suitable conductive materials, or combinations thereof.

In some embodiments, forming the first insulating material on the first gate structure of the first set of transistors of operation 702b includes performing one or more deposition processes to form one or more dielectric material layers and/or insulating material layers. In some embodiments, the one or more deposition processes to form one or more dielectric material layers and/or insulating material layers includes CVD, a PECVD, ALD, or other process suitable for depositing one or more material layers. In some embodiments, forming the first insulating material on the first gate structure of the first set of transistors includes performing one or more deposition processes to form one or more insulating material layers. In some embodiments, the first insulating material is a dielectric material. In some embodiments, the dielectric material includes silicon dioxide, silicon oxy-nitride, or the like.

In some embodiments, operation 702a and 702b are replaced by forming one or more first gate regions of the first set of transistors and one or more second gate regions of the second set of transistors, removing a portion of the first gate regions of the first set of transistors and the second gate regions of the second set of transistors, and forming an insulating material between the first gate structure of the first set of transistors and the second gate structure of the second set of transistors. In some embodiments, the gate removal process is a POLY cut process that includes one or more etching processes. In some embodiments, the gate removal process includes one or more etching processes suitable to remove a portion of the gate structure. In some embodiments, a mask is used to specify portions of the gate structure that are to be cut or removed. In some embodiments the mask is a hard mask. In some embodiments, the mask is a soft mask. In some embodiments, etching corresponds to plasma etching, reactive ion etching, chemical etching, dry etching, wet etching, other suitable processes, any combination thereof, or the like.

In some embodiments, operation 702 further includes operation 702c. In some embodiments, operation 702c includes depositing a first conductive material on at least one of a first level, a second level or a third level thereby forming at least one of a corresponding first set of contacts, a second set of contacts or a third set of contacts.

In some embodiments, the first set of contacts, the second set of contacts and the third set of contacts are part of the first set of transistors and the second set of transistors.

In some embodiments, the first set of contacts includes the set of contacts 310 or 510.

In some embodiments, the second set of contacts includes the set of contacts 312 or 512.

In some embodiments, the third set of contacts includes the set of contacts 314 or 514.

In operation 703 of method 700B, at least a first conductor on the front-side of the substrate is electrically coupled to at least a first gate of the first set of transistors by at least a back-side 303b of the substrate.

In some embodiments, the first conductor on the front-side of the substrate of method 700A-700B includes one or more conductors of the set of conductors 330, 530 or 630, the set of conductors 332, 532 or 632, the set of conductors 350, 550 or 650, the set of conductors 552 or 652, or the set of conductors 670.

FIG. 7B is a functional flow chart of a method 700B of manufacturing an IC device, in accordance with some embodiments. It is understood that additional operations may be performed before, during, and/or after the method 700B depicted in FIG. 7B, and that some other processes may only be briefly described herein.

In some embodiments, method 700B is an embodiment of operation 703 of method 700A, and similar detailed description is therefore omitted.

In operation 704 of method 700B, a first set of vias are formed on the front-side 303a of a wafer or substrate on a VD level or a VG level (e.g., VD or VG). In some embodiments, the first set of vias of method 700B includes one or more portions at least the set of vias 320, 324, 520, 524 or 624.

In some embodiments, operation 704 includes forming a first set of self-aligned contacts (SACs) in the insulating layer over the front-side 303a of the wafer. In some embodiments, the first set of vias is electrically coupled to at least the first set of transistors.

In operation 706 of method 700B, a second conductive material is deposited on the front-side 303a of the substrate on a first metal level thereby forming a first set of conductors on the front-side 303a of the wafer or substrate on a first metal level (e.g., M0).

In some embodiments, operation 706 includes at least depositing a first set of conductive regions over the front-side 303a of the integrated circuit. In some embodiments, the first set of conductors of method 700B includes one or more portions of at least the set of conductors 330, 530 or 630.

In operation 708 of method 700B, thinning is performed on the back-side 303b of the wafer or substrate. In some embodiments, operation 708 includes a thinning process performed on the back-side 303b of the semiconductor wafer or substrate. In some embodiments, the thinning process includes a grinding operation and a polishing operation (such as chemical mechanical polishing (CMP)) or other suitable processes. In some embodiments, after the thinning process, a wet etching operation is performed to remove defects formed on the back-side 303b of the semiconductor wafer or substrate.

In operation 710 of method 700B, a second set of vias are formed on the back-side 303b of the thinned wafer or substrate on a BVD level or a BVG level (e.g., BVD or BVG). In some embodiments, the second set of vias of method 700B includes one or more portions at least the set of vias 322, 326, 526 or 626.

In some embodiments, operation 710 includes forming a second set of SACs in the insulating layer over the back-side 303b of the wafer. In some embodiments, the second set of vias is electrically coupled to at least the second set of transistors.

In operation 712 of method 700B, a third conductive material is deposited on the back-side 303b of the substrate on a second metal level thereby forming a second set of conductors on the back-side 303b of the wafer or substrate on a second metal level (e.g., BM0).

In some embodiments, operation 712 includes at least depositing a second set of conductive regions over the back-side 303b of the integrated circuit. In some embodiments, the second set of conductors of method 700B includes one or more portions of at least the set of conductors 332, 532 or 632.

In operation 714 of method 700B, a third set of vias are formed on the front-side 303a of the wafer or substrate on a V0 level (e.g., V0). In some embodiments, the third set of vias of method 700B includes one or more portions of at least the set of vias 340, 540 or 640.

In some embodiments, operation 714 includes forming a third set of SACs in the insulating layer over the front-side 303a of the wafer. In some embodiments, the third set of vias is electrically coupled to at least the first set of transistors.

In operation 716 of method 700B, a fourth set of vias are formed on the back-side 303b of the thinned wafer or substrate on a BV0 level (e.g., BV0). In some embodiments, the fourth set of vias of method 700B includes one or more portions at least the set of vias 542 or 642.

In some embodiments, operation 716 includes forming a fourth set of SACs in the insulating layer over the back-side 303b of the wafer. In some embodiments, the fourth set of vias is electrically coupled to at least the second set of transistors.

In operation 718 of method 700B, a fourth conductive material is deposited on the front-side 303a of the substrate on a third metal level thereby forming a third set of conductors on the front-side 303a of the wafer or substrate on a third metal level (e.g., M1).

In some embodiments, operation 718 includes at least depositing a third set of conductive regions over the front-side 303a of the integrated circuit. In some embodiments, the third set of conductors of method 700B includes one or more portions of at least the set of conductors 350, 550 or 650.

In operation 720 of method 700B, a fifth conductive material is deposited on the back-side 303b of the substrate on a fourth metal level thereby forming a fourth set of conductors on the back-side 303b of the wafer or substrate on a fourth metal level (e.g., BMI).

In some embodiments, operation 720 includes at least depositing a fourth set of conductive regions over the back-side 303b of the integrated circuit. In some embodiments, the fourth set of conductors of method 700B includes one or more portions of at least the set of conductors 552 or 652.

In operation 722 of method 700B, a fifth set of vias are formed on the front-side 303a of the wafer or substrate on a V1 level (e.g., V1). In some embodiments, the fifth set of vias of method 700B includes one or more portions of at least the set of vias 660.

In some embodiments, operation 722 includes forming a fifth set of SACs in the insulating layer over the front-side 303a of the wafer. In some embodiments, the fifth set of vias is electrically coupled to at least the first set of transistors.

In operation 724 of method 700B, a sixth conductive material is deposited on the front-side 303a of the substrate on a fifth metal level thereby forming a fifth set of conductors on the front-side 303a of the wafer or substrate on a fifth metal level (e.g., M2).

In some embodiments, operation 724 includes at least depositing a fifth set of conductive regions over the front-side 303a of the integrated circuit. In some embodiments, the fifth set of conductors of method 700B includes one or more portions of at least the set of conductors 670.

In some embodiments, one or more of operations 702, 703, 704, 706, 710, 712, 714, 716, 718, 720, 722 or 724 of methods 700A-700B include using a combination of photolithography and material removal processes to form openings in an insulating layer (not shown) over the substrate. In some embodiments, the photolithography process includes patterning a photoresist, such as a positive photoresist or a negative photoresist. In some embodiments, the photolithography process includes forming a hard mask, an antireflective structure, or another suitable photolithography structure. In some embodiments, the material removal process includes a wet etching process, a dry etching process, an RIE process, laser drilling or another suitable etching process. The openings are then filled with conductive material, e.g., copper, aluminum, titanium, nickel, tungsten, or other suitable conductive material. In some embodiments, the openings are filled using CVD, PVD, sputtering, ALD or other suitable formation process.

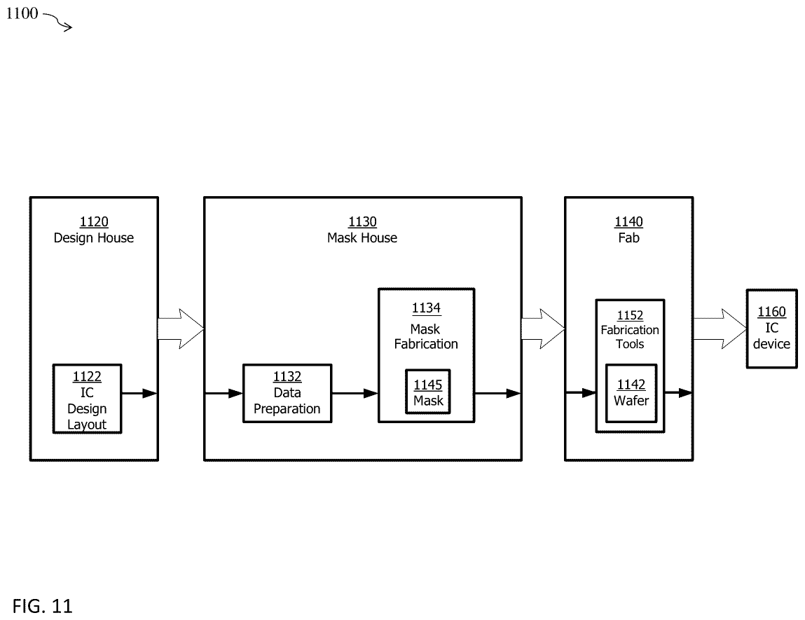

In some embodiments, at least one or more operations of method 700A-700B is performed by system 1100 of FIG. 11. In some embodiments, at least one method(s), such as method 700A-700B discussed above, is performed in whole or in part by at least one manufacturing system, including system 1100. One or more of the operations of method 700A-700B is performed by IC fab 1140 (FIG. 11) to fabricate IC device 1160. In some embodiments, one or more of the operations of method 700A-700B is performed by fabrication tools 1152 to fabricate wafer 1142.

In some embodiments, the conductive material includes copper, aluminum, titanium, nickel, tungsten, or other suitable conductive material. In some embodiments, the openings and trench are filled using CVD, PVD, sputtering, ALD or other suitable formation process. In some embodiments, after conductive material is deposited in one or more of operations 702c, 704, 706, 710, 712, 714, 716, 718, 720, 722 or 724, the conductive material is planarized to provide a level surface for subsequent steps.

In some embodiments, one or more of the operations of method 700A, 700B, 800 or 900 is not performed.

One or more of the operations of methods 800-900 is performed by a processing device configured to execute instructions for manufacturing an integrated circuit, such as at least integrated circuit 100, 300, 400A, 400B, 500 or 600. In some embodiments, one or more operations of methods 800-900 is performed using a same processing device as that used in a different one or more operations of methods 800-900. In some embodiments, a different processing device is used to perform one or more operations of methods 800-900 from that used to perform a different one or more operations of methods 800-900. In some embodiments, other order of operations of method 700A, 700B, 800 or 900 is within the scope of the present disclosure. Method 700A, 700B, 800 or 900 includes exemplary operations, but the operations are not necessarily performed in the order shown. Operations in method 700A, 700B, 800 or 900 may be added, replaced, changed order, and/or eliminated as appropriate, in accordance with the spirit and scope of disclosed embodiments.

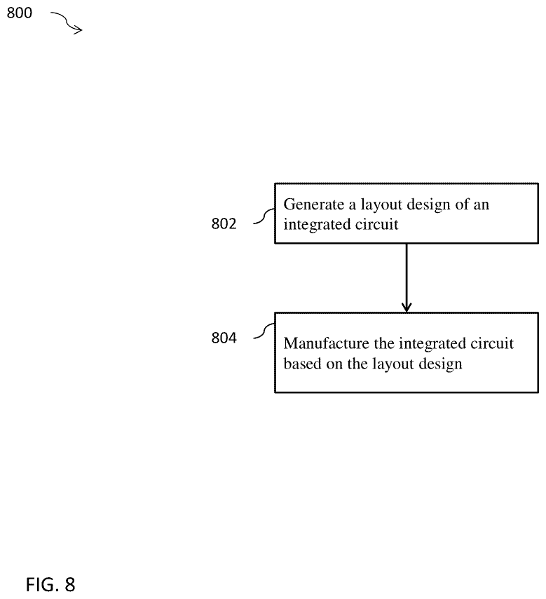

FIG. 8 is a flowchart of a method 800 of forming or manufacturing an integrated circuit in accordance with some embodiments. It is understood that additional operations may be performed before, during, and/or after the method 800 depicted in FIG. 8, and that some other operations may only be briefly described herein. In some embodiments, the method 800 is usable to form integrated circuits, such as at least integrated circuit 100, 300, 400A, 400B, 500 or 600. In some embodiments, the method 800 is usable to form integrated circuits having similar features and similar structural relationships as one or more of layout design 200.

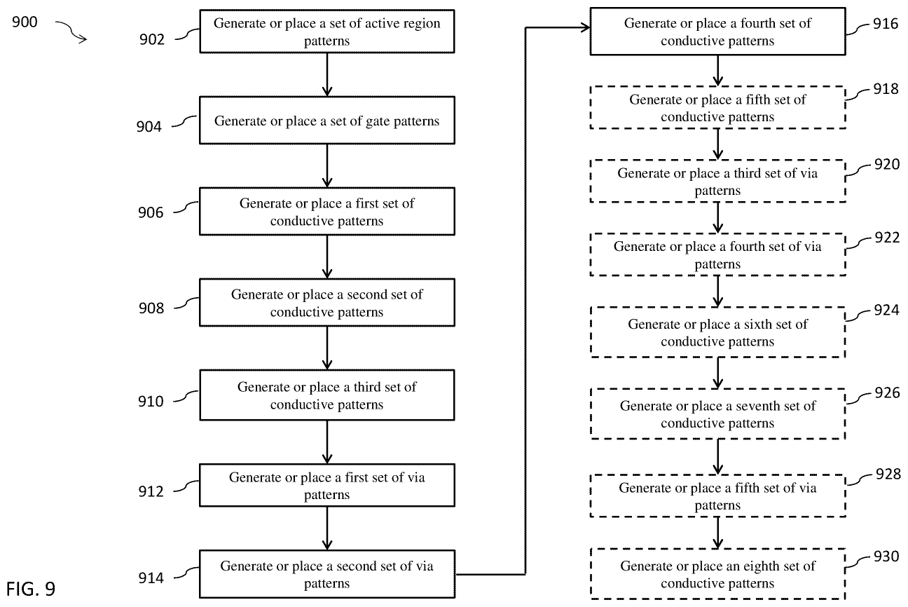

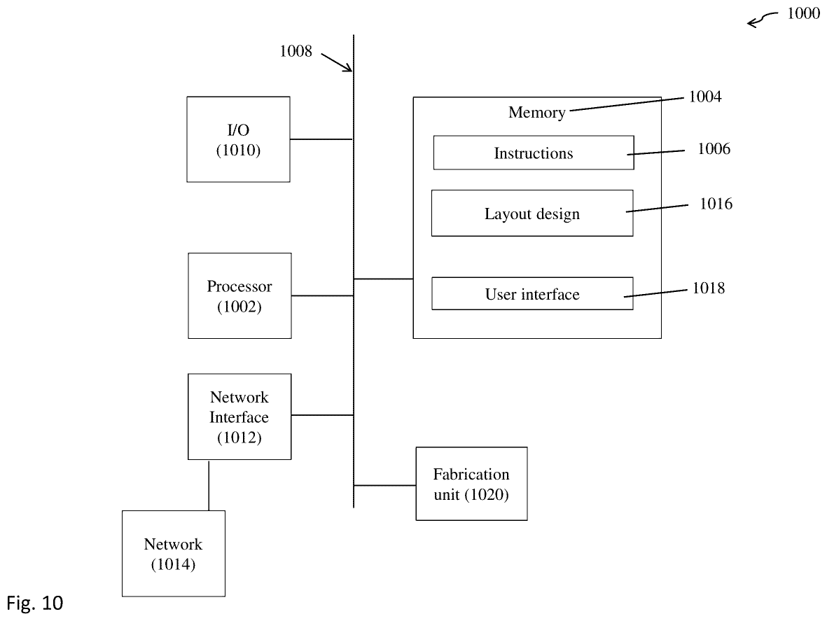

In operation 802 of method 800, a layout design of an integrated circuit is generated. Operation 802 is performed by a processing device (e.g., processor 1002 (FIG. 10)) configured to execute instructions for generating a layout design. In some embodiments, the layout design of method 800 includes one or more patterns of at least layout design 200, or one or more features similar to at least integrated circuit 100, 300, 400A, 400B, 500 or 600. In some embodiments, the layout design of the present application is in a graphic database system (GDSII) file format. In some embodiments, operation 802 corresponds to method 900 of FIG. 9.

In operation 804 of method 800, the integrated circuit is manufactured based on the layout design. In some embodiments, operation 804 of method 800 comprises manufacturing at least one mask based on the layout design, and manufacturing the integrated circuit based on the at least one mask. In some embodiments, operation 804 corresponds to method 700A-700B, of FIGS. 7A-7B.

FIG. 9 is a flowchart of a method 900 of generating a layout design of an integrated circuit, in accordance with some embodiments. It is understood that additional operations may be performed before, during, and/or after the method 900 depicted in FIG. 9, and that some other processes may only be briefly described herein. In some embodiments, method 900 is an embodiment of operation 802 of method 800. In some embodiments, method 900 is usable to generate one or more layout patterns of at least layout design 200, or one or more features similar to at least integrated circuit 100, 300, 400A, 400B, 500 or 600.

In some embodiments, method 900 is usable to generate one or more layout patterns having structural relationships including alignment, lengths and widths, as well as configurations and layers of at least layout design 200, or one or more features similar to at least integrated circuit 100, 300, 400A, 400B, 500 or 600, and similar detailed description will not be described in FIG. 9, for brevity.

In operation 902 of method 900, a set of active region patterns is generated or placed on the layout design. In some embodiments, the set of active region patterns of method 900 includes at least portions of one or more patterns of the set of active region patterns 202 or 204. In some embodiments, the set of active region patterns of method 900 includes one or more regions similar to the set of active regions 302 or 304. In some embodiments, the set of active region patterns of method 900 includes one or more patterns or similar patterns in the OD layer.

In operation 904 of method 900, a set of gate patterns is generated or placed on the layout design. In some embodiments, the set of gate patterns of method 900 includes at least portions of one or more patterns of the set of gate patterns 206 or 208. In some embodiments, the set of active gate patterns of method 900 includes one or more regions similar to the set of gates 306, 308, 506, 508, 606 or 608. In some embodiments, the set of gate patterns of method 900 includes one or more patterns or similar patterns in the POLY layer.

In operation 906 of method 900, a first set of conductive patterns is generated or placed on the layout design. In some embodiments, the first set of conductive patterns of method 900 includes at least portions of one or more patterns of the set of contact patterns 210. In some embodiments, the first set of conductive patterns of method 900 includes one or more patterns similar to the set of contacts 310 or 510. In some embodiments, the first set of conductive patterns of method 900 includes one or more patterns or similar patterns in the MD layer.

In operation 908 of method 900, a second set of conductive patterns is generated or placed on the layout design. In some embodiments, the second set of conductive patterns of method 900 includes at least portions of one or more patterns of the set of contact patterns 212. In some embodiments, the second set of conductive patterns of method 900 includes one or more patterns similar to the set of contacts 312 or 512. In some embodiments, the second set of conductive patterns of method 900 includes one or more patterns or similar patterns in the BMD layer.

In operation 910 of method 900, a third set of conductive patterns is generated or placed on the layout design. In some embodiments, the third set of conductive patterns of method 900 includes at least portions of one or more patterns of the set of contact patterns 214. In some embodiments, the third set of conductive patterns of method 900 includes one or more patterns similar to the set of contacts 314 or 514. In some embodiments, the third set of conductive patterns of method 900 includes one or more patterns or similar patterns in the MDLI layer.

In operation 912 of method 900, a first set of via patterns is generated or placed on the layout design. In some embodiments, the first set of via patterns of method 900 includes at least portions of one or more patterns of the set of via patterns 220 or 224. In some embodiments, the first set of via patterns of method 900 includes one or more via patterns similar to at least the set of vias 320, 324, 520, 524 or 624. In some embodiments, the first set of via patterns of method 900 includes one or more patterns or similar vias in the VG or VD layer.

In operation 914 of method 900, a second set of via patterns is generated or placed on the layout design. In some embodiments, the second set of via patterns of method 900 includes at least portions of one or more patterns of the set of via patterns 222 or 226. In some embodiments, the second set of via patterns of method 900 includes one or more via patterns similar to at least the set of vias 322, 326, 526 or 626. In some embodiments, the second set of via patterns of method 900 includes one or more patterns or similar vias in the BVG or BVD layer.

In operation 916 of method 900, a fourth set of conductive patterns is generated or placed on the layout design. In some embodiments, the fourth set of conductive patterns of method 900 includes at least portions of one or more patterns of at least the set of conductive patterns 230. In some embodiments, the fourth set of conductive patterns of method 900 includes one or more conductive patterns similar to at least the set of conductors 330, 530 or 630. In some embodiments, the fourth set of conductive patterns of method 900 includes one or more patterns or similar conductors in the M0 layer.

In operation 918 of method 900, a fifth set of conductive patterns is generated or placed on the layout design. In some embodiments, the fifth set of conductive patterns of method 900 includes at least portions of one or more patterns of at least the set of conductive patterns 232. In some embodiments, the fifth set of conductive patterns of method 900 includes one or more conductive patterns similar to at least the set of conductors 332, 532 or 632. In some embodiments, the fifth set of conductive patterns of method 900 includes one or more patterns or similar conductors in the BM0 layer.

In operation 920 of method 900, a third set of via patterns is generated or placed on the layout design. In some embodiments, the third set of via patterns of method 900 includes at least portions of one or more patterns of the set of via patterns 240. In some embodiments, the third set of via patterns of method 900 includes one or more via patterns similar to at least the set of vias 340, 540 or 640. In some embodiments, the third set of via patterns of method 900 includes one or more patterns or similar vias in the V0 layer.

In operation 922 of method 900, a fourth set of via patterns is generated or placed on the layout design. In some embodiments, the fourth set of via patterns of method 900 includes one or more via patterns similar to at least the set of vias 542 or 642. In some embodiments, the fourth set of via patterns of method 900 includes one or more patterns or similar vias in the BV0 layer.

In operation 924 of method 900, a sixth set of conductive patterns is generated or placed on the layout design. In some embodiments, the sixth set of conductive patterns of method 900 includes at least portions of one or more patterns of at least the set of conductive patterns 250. In some embodiments, the sixth set of conductive patterns of method 900 includes one or more conductive patterns similar to at least the set of conductors 350, 550 or 650. In some embodiments, the sixth set of conductive patterns of method 900 includes one or more patterns or similar conductors in the M1 layer.

In operation 926 of method 900, a seventh set of conductive patterns is generated or placed on the layout design. In some embodiments, the seventh set of conductive patterns of method 900 includes one or more conductive patterns similar to at least the set of conductors 552 or 652. In some embodiments, the seventh set of conductive patterns of method 900 includes one or more patterns or similar conductors in the BM1 layer.

In operation 928 of method 900, a fifth set of via patterns is generated or placed on the layout design. In some embodiments, the fifth set of via patterns of method 900 includes one or more via patterns similar to at least the set of vias 660. In some embodiments, the fifth set of via patterns of method 900 includes one or more patterns or similar vias in the V1 layer.

In operation 930 of method 900, an eighth set of conductive patterns is generated or placed on the layout design. In some embodiments, the eighth set of conductive patterns of method 900 includes one or more conductive patterns similar to at least the set of conductors 670. In some embodiments, the eighth set of conductive patterns of method 900 includes one or more patterns or similar conductors in the M2 layer.

FIG. 10 is a schematic view of a system 1000 for designing an IC layout design and manufacturing an IC circuit in accordance with some embodiments.

In some embodiments, system 1000 generates or places one or more IC layout designs described herein. System 1000 includes a hardware processor 1002 and a non-transitory, computer readable storage medium 1004 (e.g., memory 1004) encoded with, i.e., storing, the computer program code 1006, i.e., a set of executable instructions 1006. Computer readable storage medium 1004 is configured for interfacing with manufacturing machines for producing the integrated circuit. The processor 1002 is electrically coupled to the computer readable storage medium 1004 by a bus 1008. The processor 1002 is also electrically coupled to an I/O interface 1010 by bus 1008. A network interface 1012 is also electrically connected to the processor 1002 via bus 1008. Network interface 1012 is connected to a network 1014, so that processor 1002 and computer readable storage medium 1004 are capable of connecting to external elements by network 1014. The processor 1002 is configured to execute the computer program code 1006 encoded in the computer readable storage medium 1004 in order to cause system 1000 to be usable for performing a portion or all of the operations as described in method 800-900.

In some embodiments, the processor 1002 is a central processing unit (CPU), a multi-processor, a distributed processing system, an application specific integrated circuit (ASIC), and/or a suitable processing unit.

In some embodiments, the computer readable storage medium 1004 is an electronic, magnetic, optical, electromagnetic, infrared, and/or a semiconductor system (or apparatus or device). For example, the computer readable storage medium 1004 includes a semiconductor or solid-state memory, a magnetic tape, a removable computer diskette, a random access memory (RAM), a read-only memory (ROM), a rigid magnetic disk, and/or an optical disk. In some embodiments using optical disks, the computer readable storage medium 1004 includes a compact disk-read only memory (CD-ROM), a compact disk-read/write (CD-R/W), and/or a digital video disc (DVD).

In some embodiments, the storage medium 1004 stores the computer program code 1006 configured to cause system 1000 to perform method 800-900. In some embodiments, the storage medium 1004 also stores information needed for performing method 800-900 as well as information generated during performing method 800-900, such as layout design 1016, user interface 1018 and fabrication unit 1020, and/or a set of executable instructions to perform the operation of method 800-900. In some embodiments, layout design 1016 comprises one or more of layout patterns of at least layout design 200, or features similar to at least integrated circuit 100, 300, 400A, 400B, 500 or 600.

In some embodiments, the storage medium 1004 stores instructions (e.g., computer program code 1006) for interfacing with manufacturing machines. The instructions (e.g., computer program code 1006) enable processor 1002 to generate manufacturing instructions readable by the manufacturing machines to effectively implement method 800-900 during a manufacturing process.

System 1000 includes I/O interface 1010. I/O interface 1010 is coupled to external circuitry. In some embodiments, I/O interface 1010 includes a keyboard, keypad, mouse, trackball, trackpad, and/or cursor direction keys for communicating information and commands to processor 1002.

System 1000 also includes network interface 1012 coupled to the processor 1002. Network interface 1012 allows system 1000 to communicate with network 1014, to which one or more other computer systems are connected. Network interface 1012 includes wireless network interfaces such as BLUETOOTH, WIFI, WIMAX, GPRS, or WCDMA; or wired network interface such as ETHERNET, USB, or IEEE-2094. In some embodiments, method 800-900 is implemented in two or more systems 1000, and information such as layout design, and user interface are exchanged between different systems 1000 by network 1014.

System 1000 is configured to receive information related to a layout design through I/O interface 1010 or network interface 1012. The information is transferred to processor 1002 by bus 1008 to determine a layout design for producing at least integrated circuit 100, 300, 400A, 400B, 500 or 600. The layout design is then stored in computer readable medium 1004 as layout design 1016. System 1000 is configured to receive information related to a user interface through I/O interface 1010 or network interface 1012. The information is stored in computer readable medium 1004 as user interface 1018. System 1000 is configured to receive information related to a fabrication unit 1020 through I/O interface 1010 or network interface 1012. The information is stored in computer readable medium 1004 as fabrication unit 1020. In some embodiments, the fabrication unit 1020 includes fabrication information utilized by system 1000. In some embodiments, the fabrication unit 1020 corresponds to mask fabrication 1134 of FIG. 11.

In some embodiments, method 800-900 is implemented as a standalone software application for execution by a processor. In some embodiments, method 800-900 is implemented as a software application that is a part of an additional software application. In some embodiments, method 800-900 is implemented as a plug-in to a software application. In some embodiments, method 800-900 is implemented as a software application that is a portion of an EDA tool. In some embodiments, method 800-900 is implemented as a software application that is used by an EDA tool. In some embodiments, the EDA tool is used to generate a layout of the integrated circuit device. In some embodiments, the layout is stored on a non-transitory computer readable medium. In some embodiments, the layout is generated using a tool such as VIRTUOSO® available from CADENCE DESIGN SYSTEMS, Inc., or another suitable layout generating tool. In some embodiments, the layout is generated based on a netlist which is created based on the schematic design. In some embodiments, method 800-900 is implemented by a manufacturing device to manufacture an integrated circuit using a set of masks manufactured based on one or more layout designs generated by system 1000. In some embodiments, system 1000 is a manufacturing device configured to manufacture an integrated circuit using a set of masks manufactured based on one or more layout designs of the present disclosure. In some embodiments, system 1000 of FIG. 10 generates layout designs of an integrated circuit that are smaller than other approaches. In some embodiments, system 1000 of FIG. 10 generates layout designs of integrated circuit structure that occupy less area and provide better routing resources than other approaches.

FIG. 11 is a block diagram of an integrated circuit (IC) manufacturing system 1100, and an IC manufacturing flow associated therewith, in accordance with at least one embodiment of the present disclosure. In some embodiments, based on a layout diagram, at least one of (A) one or more semiconductor masks or (B) at least one component in a layer of a semiconductor integrated circuit is fabricated using manufacturing system 1100.

In FIG. 11, IC manufacturing system 1100 (hereinafter “system 1100”) includes entities, such as a design house 1120, a mask house 1130, and an IC manufacturer/fabricator (“fab”) 1140, that interact with one another in the design, development, and manufacturing cycles and/or services related to manufacturing an IC device 1160. The entities in system 1100 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, one or more of design house 1120, mask house 1130, and IC fab 1140 is owned by a single larger company. In some embodiments, one or more of design house 1120, mask house 1130, and IC fab 1140 coexist in a common facility and use common resources.

Design house (or design team) 1120 generates an IC design layout 1122. IC design layout 1122 includes various geometrical patterns designed for an IC device 1160. The geometrical patterns correspond to patterns of metal, oxide, or semiconductor layers that make up the various components of IC device 1160 to be fabricated. The various layers combine to form various IC features. For example, a portion of IC design layout 1122 includes various IC features, such as an active region, gate electrode, source electrode and drain electrode, metal lines or vias of an interlayer interconnection, and openings for bonding pads, to be formed in a semiconductor substrate (such as a silicon wafer) and various material layers disposed on the semiconductor substrate. Design house 1120 implements a proper design procedure to form IC design layout 1122. The design procedure includes one or more of logic design, physical design or place and route. IC design layout 1122 is presented in one or more data files having information of the geometrical patterns. For example, IC design layout 1122 can be expressed in a GDSII file format or DFII file format.

Mask house 1130 includes data preparation 1132 and mask fabrication 1134. Mask house 1130 uses IC design layout 1122 to manufacture one or more masks 1145 to be used for fabricating the various layers of IC device 1160 according to IC design layout 1122. Mask house 1130 performs mask data preparation 1132, where IC design layout 1122 is translated into a representative data file (RDF). Mask data preparation 1132 provides the RDF to mask fabrication 1134. Mask fabrication 1134 includes a mask writer. A mask writer converts the RDF to an image on a substrate, such as a mask (reticle) 1145 or a semiconductor wafer 1142. The IC design layout 1122 is manipulated by mask data preparation 1132 to comply with particular characteristics of the mask writer and/or requirements of IC fab 1140. In FIG. 11, mask data preparation 1132 and mask fabrication 1134 are illustrated as separate elements. In some embodiments, mask data preparation 1132 and mask fabrication 1134 can be collectively referred to as mask data preparation.

In some embodiments, mask data preparation 1132 includes optical proximity correction (OPC) which uses lithography enhancement techniques to compensate for image errors, such as those that can arise from diffraction, interference, other process effects and the like. OPC adjusts IC design layout 1122. In some embodiments, mask data preparation 1132 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1132 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during mask fabrication 1134, which may undo part of the modifications performed by OPC in order to meet mask creation rules.

In some embodiments, mask data preparation 1132 includes lithography process checking (LPC) that simulates processing that will be implemented by IC fab 1140 to fabricate IC device 1160. LPC simulates this processing based on IC design layout 1122 to create a simulated manufactured device, such as IC device 1160. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout 1122.

It should be understood that the above description of mask data preparation 1132 has been simplified for the purposes of clarity. In some embodiments, data preparation 1132 includes additional features such as a logic operation (LOP) to modify the IC design layout according to manufacturing rules. Additionally, the processes applied to IC design layout 1122 during data preparation 1132 may be executed in a variety of different orders.

After mask data preparation 1132 and during mask fabrication 1134, a mask 1145 or a group of masks 1145 are fabricated based on the modified IC design layout 1122. In some embodiments, mask fabrication 1134 includes performing one or more lithographic exposures based on IC design layout 1122. In some embodiments, an electron-beam (c-beam) or a mechanism of multiple e-beams is used to form a pattern on a mask (photomask or reticle) 1145 based on the modified IC design layout 1122. The mask 1145 can be formed in various technologies. In some embodiments, the mask 1145 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary version of mask 1145 includes a transparent substrate (e.g., fused quartz) and an opaque material (e.g., chromium) coated in the opaque regions of the binary mask. In another example, the mask 1145 is formed using a phase shift technology. In the phase shift mask (PSM) version of mask 1145, various features in the pattern formed on the mask are configured to have proper phase difference to enhance the resolution and imaging quality. In various examples, the phase shift mask can be attenuated PSM or alternating PSM. The mask(s) generated by mask fabrication 1134 is used in a variety of processes. For example, such a mask(s) is used in an ion implantation process to form various doped regions in the semiconductor wafer, in an etching process to form various etching regions in the semiconductor wafer, and/or in other suitable processes.

IC fab 1140 is an IC fabrication entity that includes one or more manufacturing facilities for the fabrication of a variety of different IC products. In some embodiments, IC Fab 1140 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry entity.

IC fab 1140 includes wafer fabrication tools 1152 (hereinafter “fabrication tools 1152”) configured to execute various manufacturing operations on semiconductor wafer 1142 such that IC device 1160 is fabricated in accordance with the mask(s), e.g., mask 1145. In various embodiments, fabrication tools 1152 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1140 uses mask(s) 1145 fabricated by mask house 1130 to fabricate IC device 1160. Thus, IC fab 1140 at least indirectly uses IC design layout 1122 to fabricate IC device 1160. In some embodiments, a semiconductor wafer 1142 is fabricated by IC fab 1140 using mask(s) 1145 to form IC device 1160. In some embodiments, the IC fabrication includes performing one or more lithographic exposures based at least indirectly on IC design layout 1122. Semiconductor wafer 1142 includes a silicon substrate or other proper substrate having material layers formed thereon. Semiconductor wafer 1142 further includes one or more of various doped regions, dielectric features, multilevel interconnects, and the like (formed at subsequent manufacturing steps).

System 1100 is shown as having design house 1120, mask house 1130 or IC fab 1140 as separate components or entities. However, it is understood that one or more of design house 1120, mask house 1130 or IC fab 1140 are part of the same component or entity.

One aspect of this description relates to an integrated circuit. In some embodiments, the integrated circuit includes a first gate on a first level. In some embodiments, the integrated circuit further includes a second gate on a second level below the first level, and being coupled to the first gate. In some embodiments, the integrated circuit further includes a third gate on the first level, and being separated from the first gate in a first direction. In some embodiments, the integrated circuit further includes a fourth gate on the second level, being separated from the second gate in the first direction, and being coupled to the third gate. In some embodiments, the integrated circuit further includes a first input pin extending in a second direction different from the first direction, being on a first metal layer above a front-side of a substrate, being coupled to at least the first gate, and being configured to receive a first input signal. In some embodiments, the integrated circuit further includes a first conductor extending in the first direction, being on a second metal layer below a back-side of the substrate opposite from the front-side of the substrate, and the first conductor being coupled to at least the second gate and the fourth gate. In some embodiments, the first input pin is electrically coupled to the third gate by at least the first gate, the second gate or the fourth gate.

Another aspect of this description relates to an integrated circuit. In some embodiments, the integrated circuit includes a first transistor stack on a substrate. In some embodiments, the first transistor stack includes a first transistor of a first type, the first transistor including a first gate on a first level. In some embodiments, the first transistor stack further includes a second transistor of a second type different from the first type, and the second transistor including a second gate on a second level below the first level. In some embodiments, the integrated circuit further includes a second transistor stack on the substrate. In some embodiments, the second transistor stack includes a third transistor of the first type, the third transistor including a third gate on the first level, and being separated from the first gate in a first direction. In some embodiments, the second transistor stack further includes a fourth transistor of the second type, the fourth transistor including a fourth gate on the second level, and being separated from the third gate in the first direction. In some embodiments, the integrated circuit further includes a first input pin extending in a second direction, being on a first metal layer above a front-side of the substrate, and being coupled to the first transistor and the second transistor. In some embodiments, the integrated circuit further includes a first conductor extending in the first direction, being on a second metal layer below a back-side of the substrate opposite from the front-side of the substrate, and the first conductor being coupled to the third gate and the fourth gate. In some embodiments, the first input pin is electrically coupled to the third gate from the back-side of the substrate.

Still another aspect of this description relates to a method of fabricating an integrated circuit. In some embodiments, the method includes fabricating a first set of transistors and a second set of transistors in a front-side of a substrate, the first set of transistors being stacked above the second set of transistors, the first set of transistors including a first transistor and a second transistor, the second set of transistors including a third transistor and a fourth transistor. In some embodiments, the method includes electrically coupling at least a first conductor on the front-side of the substrate to at least a first gate of the first set of transistors by at least a back-side of the substrate. In some embodiments, electrically coupling at least the first conductor on the front-side of the substrate to at least the first gate of the first set of transistors by at least the back-side of the substrate includes fabricating a first set of vias on the front-side of the substrate, the first set of vias being electrically coupled to at least the first set of transistors. In some embodiments, electrically coupling at least the first conductor on the front-side of the substrate to at least the first gate of the first set of transistors by at least the back-side of the substrate further includes depositing a first conductive material on the front-side of the substrate on a first metal level thereby forming a first set of conductors, the first set of conductors being electrically coupled to at least the first set of transistors by the first set of vias, the first set of conductors including at least the first conductor. In some embodiments, electrically coupling at least the first conductor on the front-side of the substrate to at least the first gate of the first set of transistors by at least the back-side of the substrate further includes fabricating a second set of vias on the back-side of a thinned substrate, the second set of vias being electrically coupled to at least the second set of transistors. In some embodiments, electrically coupling at least the first conductor on the front-side of the substrate to at least the first gate of the first set of transistors by at least the back-side of the substrate further includes depositing a second conductive material on the back-side of the thinned substrate on a second metal level thereby forming a second set of conductors, the second set of conductors being electrically coupled to at least the second set of transistors by the second set of vias.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. An integrated circuit, comprising:
a first gate on a first level;
a second gate on a second level below the first level, and being coupled to the first gate;
a third gate on the first level, and being separated from the first gate in a first direction;
a fourth gate on the second level, being separated from the second gate in the first direction, and being coupled to the third gate; and
a first input pin extending in a second direction different from the first direction, being on a first metal layer above a front-side of a substrate, being coupled to at least the first gate, and being configured to receive a first input signal; and
a first conductor extending in the first direction, being on a second metal layer below a back-side of the substrate opposite from the front-side of the substrate, and the first conductor being coupled to at least the second gate and the fourth gate,
wherein the first input pin is electrically coupled to the third gate by at least the first gate, the second gate or the fourth gate.

2. The integrated circuit of claim 1, wherein the first input pin comprises:
a second conductor extending in the second direction, being on the first metal layer, the second conductor being next to the first gate.

3. The integrated circuit of claim 2, further comprising:
a third conductor extending in the first direction, being on a third metal layer above the front-side of the substrate, the third metal layer being different from the first metal layer and the second metal layer, and the third conductor overlapping the first gate and the second gate; and
a first via electrically coupling the third conductor and the second conductor together, the first via being between the third conductor and the second conductor.

4. The integrated circuit of claim 3, further comprising:
a second via electrically coupling the third conductor and the first gate together, the second via being between the third conductor and the first gate.

5. The integrated circuit of claim 4, further comprising:
a third via electrically coupling the first conductor and the second gate together, the third via being between the first conductor and the second gate.

6. The integrated circuit of claim 5, further comprising:
a fourth via electrically coupling the first conductor and the fourth gate together, the fourth via being between the first conductor and the fourth gate.

7. The integrated circuit of claim 1, further comprising:
a fifth gate on the first level, and being separated from the first gate and the third gate in the first direction;
a sixth gate on the second level, being separated from the second gate and the fourth gate in the first direction, and being coupled to the fifth gate; and
a second input pin extending in the second direction, being on the first metal layer, being coupled to at least the fifth gate or the sixth gate, and being configured to receive a second input signal.

8. The integrated circuit of claim 7, wherein the second input pin comprises:
a second conductor extending in the second direction, being on the first metal layer, the second conductor being between the fifth gate and the third gate.

9. The integrated circuit of claim 8, further comprising:
a third conductor extending in the first direction, being on a third metal layer above the front-side of the substrate, the third metal layer being different from the first metal layer and the second metal layer, and the third conductor overlapping the fifth gate and the sixth gate.

10. The integrated circuit of claim 9, further comprising:
a first via electrically coupling the third conductor and the second conductor together, the first via being between the third conductor and the second conductor; and
a second via electrically coupling the third conductor and the fifth gate together, the second via being between the third conductor and the fifth gate.

11. The integrated circuit of claim 10, further comprising:
a seventh gate on the first level, and being between the fifth gate and the third gate in the first direction; and
an eighth gate on the second level, being between the sixth gate and the fourth gate in the first direction, and being coupled to the seventh gate.

12. The integrated circuit of claim 11, further comprising:
a third via electrically coupling the third conductor and the seventh gate together, the third via being between the third conductor and the seventh gate.

13. An integrated circuit, comprising:
a first transistor stack on a substrate, the first transistor stack comprising:
a first transistor of a first type, the first transistor including a first gate on a first level; and
a second transistor of a second type different from the first type, and the second transistor including a second gate on a second level below the first level;
a second transistor stack on the substrate, the second transistor stack comprising:
a third transistor of the first type, the third transistor including a third gate on the first level, and being separated from the first gate in a first direction; and
a fourth transistor of the second type, the fourth transistor including a fourth gate on the second level, and being separated from the third gate in the first direction;
a first input pin extending in a second direction, being on a first metal layer above a front-side of the substrate, and being coupled to the first transistor and the second transistor; and
a first conductor extending in the first direction, being on a second metal layer below a back-side of the substrate opposite from the front-side of the substrate, and the first conductor being coupled to the third gate and the fourth gate,
wherein the first input pin is electrically coupled to the third gate from the back-side of the substrate.

14. The integrated circuit of claim 13, wherein the first input pin comprises:
a second conductor extending in the second direction, being on the first metal layer, the second conductor being next to the first gate, and being coupled to the first transistor and the second transistor.

15. The integrated circuit of claim 14, further comprising:
a third conductor extending in the first direction, being on a third metal layer above the front-side of the substrate, the third metal layer being different from the first metal layer and the second metal layer, the third conductor being overlapped by the second conductor, and the third conductor overlapping the first gate and the second gate.

16. The integrated circuit of claim 15, further comprising:
a first via electrically coupling the third conductor and the second conductor together, the first via being between the third conductor and the second conductor; and
a second via electrically coupling the third conductor and the first gate together, the second via being between the third conductor and the first gate.

17. The integrated circuit of claim 16, further comprising:
a third via electrically coupling the first conductor and the second gate together, the third via being between the first conductor and the second gate; and
a fourth via electrically coupling the first conductor and the fourth gate together, the fourth via being between the first conductor and the fourth gate.

18. The integrated circuit of claim 13, wherein the first transistor, the second transistor, the third transistor and the fourth transistor are part of a NOR logic gate circuit.

19. The integrated circuit of claim 13, wherein
the first gate extends in the second direction, and overlaps the first conductor;
the second gate extends in the second direction, and overlaps the first conductor;
the third gate extends in the second direction, and overlaps the first conductor; and
the fourth gate extends in the second direction, and overlaps the first conductor.

20. A method of fabricating an integrated circuit, the method comprising:
fabricating a first set of transistors and a second set of transistors in a front-side of a substrate, the first set of transistors being stacked above the second set of transistors, the first set of transistors including a first transistor and a second transistor, the second set of transistors including a third transistor and a fourth transistor; and
electrically coupling at least a first conductor on the front-side of the substrate to at least a first gate of the first set of transistors by at least a back-side of the substrate, wherein electrically coupling at least the first conductor on the front-side of the substrate to at least the first gate of the first set of transistors by at least the back-side of the substrate comprises:
fabricating a first set of vias on the front-side of the substrate, the first set of vias being electrically coupled to at least the first set of transistors;
depositing a first conductive material on the front-side of the substrate on a first metal level thereby forming a first set of conductors, the first set of conductors being electrically coupled to at least the first set of transistors by the first set of vias, the first set of conductors including at least the first conductor;
fabricating a second set of vias on the back-side of a thinned substrate, the second set of vias being electrically coupled to at least the second set of transistors; and
depositing a second conductive material on the back-side of the thinned substrate on a second metal level thereby forming a second set of conductors, the second set of conductors being electrically coupled to at least the second set of transistors by the second set of vias.
